(19) United States
(12) Patent Application Publication
(10) Pub. No.: US 2017/0018685 A1
(43) Pub. Date: Jan. 19, 2017

(54) METHOD OF MANUFACTURING LIGHT-EMITTING DIODE

(71) Applicant: SAMSUNG ELECTRONICS CO., LTD., Suwon-si (KR)

(72) Inventors: Dong-hyun CHO, Hwaseong-si (KR); Taek-sung KIM, Yongin-si (KR); Nam-goo CHA, Hwaseong-si (KR)

(73) Assignee: SAMSUNG ELECTRONICS CO., LTD., Suwon-si (KR)

(21) Appl. No.: 15/151,017

(22) Filed: May 10, 2016

(30) Foreign Application Priority Data
Jul. 14, 2015 (KR) 10-2015-0099842

(51) Int. Cl. H01L 33/42; H01L 33/38; H01L 27/15

(52) U.S. Cl. CPC H01L 33/42; H01L 27/153; H01L 33/387; H01L 2933/0016

(57) ABSTRACT

A method of manufacturing a light-emitting diode (LED) includes preparing a substrate, forming a plurality of semiconductor light-emitting units on the substrate, each of the plurality of semiconductor light-emitting units protruding from the substrate and including a first conductive semiconductor layer, and an active layer and a second conductive semiconductor layer, the active layer and the second conductive semiconductor layer sequentially covering the first conductive semiconductor layer, dipping the semiconductor light-emitting units into an aqueous solution containing metal salt and an alkaline ligand compound, and forming an electrode layer on the plurality of semiconductor light-emitting units, wherein the forming the electrode layer includes maintaining a temperature of the aqueous solution between about 40° C. and about 200° C.

### CROSS-REFERENCE TO RELATED APPLICATION

This application claims priority from Korean Patent Application No. 10-2015-0099842, filed on Jul. 14, 2015, in the Korean Intellectual Property Office, the disclosure of which is incorporated herein by reference in its entirety.

### BACKGROUND

1. Field

Methods consistent with exemplary embodiments relate to a method of manufacturing a light-emitting diode (LED), and more particularly, to a method of uniformly forming transparent electrodes by performing low temperature liquid phase deposition on a plurality of nanostructure semiconductor light-emitting units.

2. Description of the Related Art

In comparison to other light sources in the related art, LEDs are known as a next generation light source with advantages such as long durability, low power consumption, fast response speed, environmental-friendliness, and the like. From among the LEDs, nano LEDs include nanostructure semiconductor light-emitting units having a large light emission area. The nano LEDs exhibit high light emission efficiency due to the nanostructure semiconductor light-emitting units. In such nano LEDs, forming transparent electrodes is essential for uniformly supplying current to the nanostructure semiconductor light-emitting units.

### SUMMARY

One or more exemplary embodiments provide a method of manufacturing a light-emitting diode (LED) including uniformly forming transparent electrodes by performing low temperature liquid phase deposition on a nanostructure semiconductor light-emitting unit that forms a nano LED.

Additional aspects will be set forth in part in the description which follows and, in part, will be apparent from the description, or may be learned by practice of the exemplary embodiments.

According to an aspect of an exemplary embodiment, there is provided a method of manufacturing a light-emitting diode (LED), the method including preparing a substrate, forming a plurality of semiconductor light-emitting units on the substrate, each of the semiconductor light-emitting units protruding from the substrate and including a first conductive semiconductor layer as a core, and an active layer and a second conductive semiconductor layer as a shell that sequentially covers the first conductive semiconductor layer, dipping the semiconductor light-emitting units into an aqueous solution containing metal salt and an alkaline ligand compound, and forming an electrode layer on the semiconductor light-emitting units. The forming of the electrode layer includes maintaining a temperature of the aqueous solution to about 40° C. to about 200° C.

In an exemplary embodiment, the method further includes, after the forming of the electrode layer, forming a filler at a side surface of the electrode layer.

In an exemplary embodiment, the metal salt is zinc salt, the alkaline ligand compound is ammonia, and the electrode layer is a zinc oxide layer and is transparent.

In an exemplary embodiment, the pH of the aqueous solution is about 10 to about 12.

In an exemplary embodiment, the aqueous solution contains about 0.1 mM to about 1000 mM of metal salt.

In an exemplary embodiment, an aspect ratio of each of the semiconductor light-emitting units is at least 10:1.

In an exemplary embodiment, the forming of the semiconductor light-emitting units includes forming the first conductive semiconductor layer as protruding units spaced apart at uniform intervals on the substrate, forming the active layer, the active layer covering side surfaces and upper surface of the first conductive semiconductor layer, and forming the second conductive semiconductor layer, the second conductive semiconductor layer covering side surfaces and upper surfaces of the active layer.

In an exemplary embodiment, the forming the first conductive semiconductor layer as the protruding units spaced apart at uniform intervals on the substrate includes forming a base layer on the substrate, forming, on the base layer, a mask layer including an opening, and selectively growing the first conductive semiconductor layer in the opening, using the base layer as a growth surface.

In an exemplary embodiment, the forming of the electrode layer includes conformally forming the electrode layer such that the electrode layer covers side surfaces and upper surfaces of the semiconductor light-emitting units.

In an exemplary embodiment, a step coverage of the electrode layer is about 70% or above.

According to an aspect of another exemplary embodiment, there is provided a method of manufacturing a light-emitting diode (LED), the method including preparing a substrate, forming a plurality of semiconductor light-emitting units on the substrate, each of the semiconductor light-emitting units protruding from the substrate and including a first conductive semiconductor layer as a core, and an active layer and a second conductive semiconductor layer as a shell that sequentially covers the first conductive semiconductor layer, dipping the semiconductor light-emitting units into an oxidized solution containing a metal source, and forming an electrode layer on the semiconductor light-emitting units. The forming of the electrode layer includes maintaining a temperature of the oxidized solution to about 0° C. to about 100° C.

In an exemplary embodiment, the method further includes, after the forming of the electrode layer, removing impurities by irradiating the electrode layer with ultraviolet rays.

In an exemplary embodiment, the metal source is zinc foil, the oxidized solution is an amide-based solution, and the electrode layer is a zinc oxide layer.

In an exemplary embodiment, the electrode layer is transparent.

In an exemplary embodiment, the forming of the electrode layer includes conformally forming the electrode layer such that the electrode layer covers side surfaces and upper surfaces of the semiconductor light-emitting units.

According to an aspect of another exemplary embodiment, there is provided a method of manufacturing a light-emitting diode (LED), the method including: preparing a substrate; forming a plurality of semiconductor light-emitting units on the substrate, each of the plurality of semiconductor light-emitting units protruding from the substrate and including: a first conductive semiconductor layer; an active layer; and a second conductive semiconductor layer, the active layer and the second conductive semiconductor layer sequentially covering the first conductive semiconductor layer; dipping the semiconductor light-emitting units into an aqueous solution including: metal salt; and an alkaline ligand compound; and forming an electrode layer on the plurality of semiconductor light-emitting units, wherein the forming the electrode layer includes maintaining a temperature of the aqueous solution between about 40° C. and about 200° C.

The method may further include, after the forming the electrode layer, filling spaces between the plurality of semiconductor light-emitting units with a filler.

The metal salt may include zinc salt, the alkaline ligand compound may include ammonia, and the electrode layer may include a zinc oxide layer and is transparent.

pH of the aqueous solution is between about 10 and about 12.

The aqueous solution may include about 0.1 mM to about 1000 mM of the metal salt.

An aspect ratio of each of the plurality of semiconductor light-emitting units is at least 10:1.

The forming the plurality of semiconductor light-emitting units may include: forming the first conductive semiconductor layer including a plurality of protruding units spaced apart from one another at uniform intervals on the substrate; forming the active layer, the active layer covering side surfaces and upper surfaces of the plurality of protruding units; and forming the second conductive semiconductor layer, the second conductive semiconductor layer covering side surfaces and upper surfaces of the active layer.

The forming the first conductive semiconductor layer may include: forming a base layer on the substrate; forming, on the base layer, a mask layer including an opening; and selectively growing the first conductive semiconductor layer in the opening, using the base layer as a growth surface of the first conductive semiconductor layer.

The forming the electrode layer includes conformally forming the electrode layer such that the electrode layer covers side surfaces and upper surfaces of the semiconductor light-emitting units.

A step coverage of the electrode layer may be about 70% or above.

The step coverage may correspond to a ratio of a thickness of a thickest portion of the electrode layer to a thickness of a thinnest portion of the electrode layer.

According to an aspect of another exemplary embodiment, there is provided a method of manufacturing a light-emitting diode (LED), the method including: preparing a substrate; forming a plurality of semiconductor light-emitting units on the substrate, each of the plurality of semiconductor light-emitting units protruding from the substrate and including: a core including a first conductive semiconductor layer; and a shell including: an active layer; and a second conductive semiconductor layer, the active layer and the second conductive semiconductor layer sequentially covering the first conductive semiconductor layer; dipping the plurality of semiconductor light-emitting units into an oxidized solution containing a metal source; and forming an electrode layer on the plurality of semiconductor light-emitting units, wherein the forming the electrode layer includes maintaining a temperature of the oxidized solution between about 0° C. and about 100° C.

The method may further include, after the forming the electrode layer, irradiating the electrode layer with ultraviolet rays.

The metal source may include a zinc foil, the oxidized solution may include an amide-based solution, and the electrode layer may include a zinc oxide layer.

The electrode layer may be transparent.

The forming the electrode layer may include conformally forming the electrode layer such that the electrode layer covers side surfaces and upper surfaces of the plurality of semiconductor light-emitting units.

According to an aspect of another exemplary embodiment, there is provided a method of manufacturing a light-emitting diode (LED), the method including: preparing a substrate; forming a plurality of semiconductor light-emitting units on the substrate, each of the plurality of semiconductor light-emitting units protruding from the substrate and including: a core including a first conductive semiconductor layer; and a shell including: an active layer; and a second conductive semiconductor layer, the active layer and the second conductive semiconductor layer sequentially covering the first conductive semiconductor layer; and dipping the plurality of semiconductor light-emitting units into an aqueous solution to coat each of the plurality of semiconductor light-emitting units with a transparent electrode layer, the aqueous solution including: zinc salt; and ammonia, wherein the dipping the plurality of semiconductor light-emitting units includes maintaining a temperature of the aqueous solution lower than about 200° C.

The dipping the plurality of semiconductor light-emitting units may include maintaining the temperature of the aqueous solution between about 40° C. and about 200° C.

A ratio of a thickness of a thickest portion of the transparent electrode layer to a thickness of a thinnest portion of the transparent electrode layer is greater than or equal to 70%.

The method may further include changing a ratio of Zn²⁺ ions of the zinc salt and the ammonia to control a growing speed of the transparent electrode layer.

### BRIEF DESCRIPTION OF THE DRAWINGS

Exemplary embodiments of the inventive concept will be more clearly understood from the following detailed description taken in conjunction with the accompanying drawings in which:

FIGS. 1A and 1B are schematic perspective views of a plurality of semiconductor light-emitting units in which a transparent electrode layer is formed by using a light-emitting diode (LED) manufacturing method according to an exemplary embodiment;

FIGS. 2 to 12 are diagrams for describing an LED manufacturing method according to an exemplary embodiment;

FIGS. 13 and 14 are diagrams for describing the formation of a transparent electrode layer via low temperature liquid phase deposition, according to an exemplary embodiment;

FIGS. 15 and 16 are cross-sectional views of a white light source module including an LED manufactured by using an LED manufacturing method according to an exemplary embodiment;

FIGS. 17A and 17B are cross-sectional views of a white light source module, which is adoptable in a lighting device as an LED manufactured by using an LED manufacturing method according to an exemplary embodiment;

FIG. 18 is a CIE chromaticity diagram showing a perfect radiator spectrum that is usable for an LED manufactured by using an LED manufacturing method according to an exemplary embodiment;

FIG. 19 is a cross-sectional view of a quantum dot as a wavelength conversion material that is usable for an LED manufactured by using an LED manufacturing method according to an exemplary embodiment;

FIG. 20 is a perspective view of a backlight unit including an LED manufactured by using an LED manufacturing method according to an exemplary embodiment;

FIG. 21 is a cross-sectional view of a direct-type backlight unit including an LED manufactured by using an LED manufacturing method according to an exemplary embodiment;

FIG. 22 is a plan view of a backlight unit including an LED manufactured by using an LED manufacturing method according to an exemplary embodiment;

FIG. 23 is a cross-sectional view of a direct-type backlight unit including an LED manufactured by using an LED manufacturing method according to an exemplary embodiment;

FIG. 24 is an enlarged diagram of a light source module of FIG. 23;

FIG. 25 is a cross-sectional view of a direct-type backlight unit including an LED manufactured by using an LED manufacturing method according to an exemplary embodiment;

FIGS. 26 to 28 are cross-sectional views of a direct-type backlight unit including an LED manufactured by using an LED manufacturing method according to an exemplary embodiment;

FIG. 29 is an exploded perspective view of a display apparatus including an LED manufactured by using an LED manufacturing method according to an exemplary embodiment;

FIG. 30 is a perspective view of a flat-panel lighting device including an LED manufactured by using an LED manufacturing method according to an exemplary embodiment;

FIG. 31 is an exploded perspective view of a lighting device including an LED manufactured by using an LED manufacturing method according to an exemplary embodiment;

FIG. 32 is an exploded perspective view of a bar-type lighting device including an LED manufactured by using an LED manufacturing method according to an exemplary embodiment;

FIG. 33 is an exploded perspective view of a lighting device including an LED manufactured by using an LED manufacturing method according to an exemplary embodiment;

FIG. 34 is a schematic diagram of an indoor light control network system including an LED manufactured by using an LED manufacturing method according to an exemplary embodiment;

FIG. 35 is a schematic diagram of a network system including an LED manufactured by using an LED manufacturing method according to an exemplary embodiment;

FIG. 36 is a block diagram for describing communication operations between a smart engine of a lighting apparatus including an LED manufactured by using an LED manufacturing method according to an exemplary embodiment and a mobile device; and

FIG. 37 is a block diagram of a smart lighting system including an LED manufactured by using an LED manufacturing method according to an exemplary embodiment.

### DETAILED DESCRIPTION

Hereinafter, exemplary embodiments will be described more fully with reference to the accompanying drawings, in which exemplary embodiments of the inventive concept are shown. This inventive concept may, however, be embodied in many different forms and should not be construed as being limited to the exemplary embodiments set forth herein. Rather, the exemplary embodiments are provided so that this disclosure will be thorough and complete, and will fully convey the scope of the inventive concept to one of ordinary skill in the art. Sizes of components in the drawings may be exaggerated for convenience of explanation. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “formed on” or “contacts” another element, the element may be directly touching or connected to the other element, or intervening elements may be present. However, when an element is referred to as being “directly formed on” or “directly contacts” another element, intervening elements may not be present. Other expressions that describe relationships between elements, such as “between” and “directly between,” may also be understood similarly to the above description.

While such terms as “first,” “second,” etc., may be used to describe various components, such components must not be limited to the above terms. The above terms are used only to distinguish one component from another. For example, within the scope of the inventive concept, a first component may be referred to as a second component, and vice versa.

An expression used in the singular encompasses the expression of the plural, unless it has a clearly different meaning in the context. In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Unless defined otherwise, terms that are used to describe the exemplary embodiments have the same meaning as commonly understood by one of ordinary skill in the art. Hereinafter, exemplary embodiments will be described with reference to the accompanying drawings.

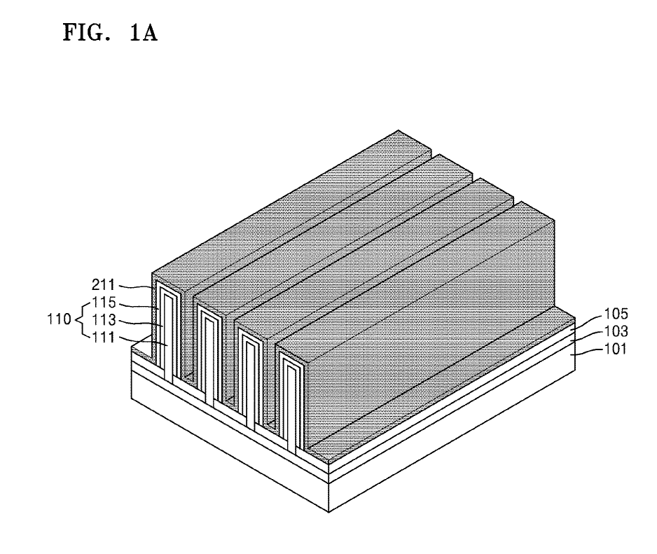

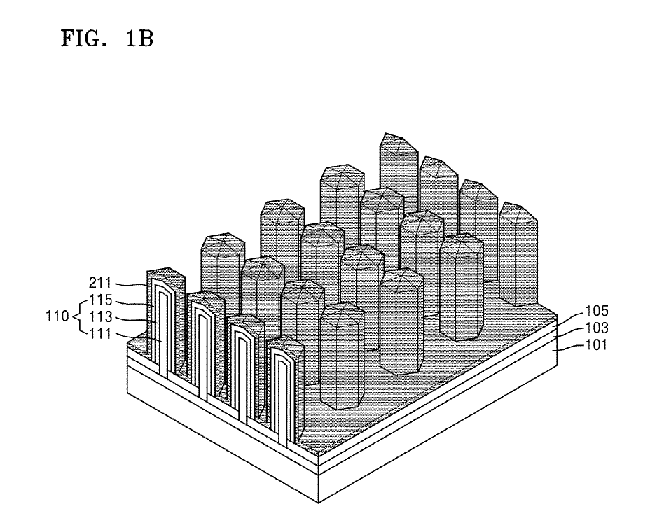

FIGS. 1A and 1B are schematic perspective views of a plurality of semiconductor light-emitting units 110 in which a transparent electrode layer 211 is formed by using a light-emitting diode (LED) manufacturing method according to an exemplary embodiment.

Referring to FIGS. 1A and 1B, a plurality of semiconductor light-emitting units 110 are covered with a transparent electrode layer 211. The semiconductor light-emitting units 110 covered with the transparent electrode layer 211 may have a nanostructure and be provided on a substrate 101.

A base layer 103 is on the substrate 101. The base layer 103 may be a first conductive semiconductor layer that provides a growth surface for the semiconductor light-emitting units 110. A mask layer 105 may be formed on the base layer 103 and have openings for growing nano cores of the semiconductor light-emitting units 110. The mask layer 105 may include a dielectric material, for example, silicon oxide (SiO₂) or silicon nitride (SiNₓ). The mask layer 105 may function as an insulating layer for electrically separating the nano cores.

In the semiconductor light-emitting units 110, nano cores may be formed by selectively growing a first conductive semiconductor layer 111 by using the mask layer 105 having openings, and an active layer 113 and a second conductive semiconductor layer 115 may be formed on surfaces of the nano cores (i.e., the first conductive semiconductor layer 111) as a shell. Thus, the semiconductor light-emitting units 110 may have a core-shell structure including the nano cores, which are formed from the first conductive semiconductor layer 111, and the shell, which is formed of the active layer 113 that covers side surfaces and upper surfaces of the nano cores (i.e., the first conductive semiconductor layer 111) and the second conductive semiconductor layer 115 that covers side surfaces and upper surfaces of the active layer 113.

The semiconductor light-emitting units 110 according to the exemplary embodiment are shown as strips with a core-shell structure in FIG. 1A and as nano rods in FIG. 1B. However, the exemplary embodiments are not limited thereto, and the semiconductor light-emitting units 110 may be shaped, for example, as pyramids, triangular pyramids, or cylinders with sharp ends.

Respective widths, heights, elements, or doping concentrations of the semiconductor light-emitting units 110 may vary so that a single LED emits light with at least two different wavelengths. White light may be provided by the LED by appropriately adjusting light with different wavelengths, without using a phosphor. Also, various colors of light or white light with different color temperatures may be provided by combining an LED including the semiconductor light-emitting units 110 with another LED or combining wavelength conversion materials such as a phosphor.

For example, referring to FIG. 1B, a nano rod structure may include hexagonal prisms, and each of the nano rod structures may have a diameter of about 50 nm to about 800 nm. Respective diameters of the nano rod structures or distances between the nano rod structures may be the same or different. When the nano rod structures have different diameters, light with different wavelengths may be emitted from each nano rod structure. A nano rod structure with a large diameter may emit light with a long wavelength. An area where a distance between the nano rod structures is large may emit light with a longer wavelength than an area where the distance between the adjacent nano rod structures is small. The distance between the nano rod structures may be about 100 nm to about 500 μm.

An electrode layer may cover the semiconductor light-emitting units 110. The electrode layer may include the transparent electrode layer 211. The transparent electrode layer 211 may form an ohmic contact with the second conductive semiconductor layer 115. The transparent electrode layer 211 may be conformally formed on side surfaces and upper surfaces of the semiconductor light-emitting units 110 to uniformly supply current to the semiconductor light-emitting units 110.

A transparent electrode layer 211 is formed by depositing materials such as indium tin oxide (ITO) via physical vapor deposition (PVD), such as e-beam deposition or sputtering. When PVD is used during a deposition process, the transparent electrode layer 211 may not be able to fill spaces between semiconductor light-emitting units, because of a high aspect ratio the semiconductor light-emitting units may have due to low step coverage and nano-sized intervals between the semiconductor light-emitting units.

In a plurality of semiconductor light-emitting units 110 with a high-density nanostructure, forming a transparent electrode layer 211 to a desired thickness or greater to increase a large light emission area may be physically difficult by using PVD.

Therefore, chemical vapor deposition (CVD) may be used to form a thin film on a highly dense unit. However, a method of generating a material for manufacturing the transparent electrode layer 211 via CVD has not yet been fully developed, and even when the transparent electrode layer 211 may be manufactured via CVD, productivity may be low because of a low manufacturing speed.

According to an exemplary embodiment, the low temperature liquid phase deposition is proposed as the method of manufacturing the transparent electrode layer. The low temperature liquid phase deposition is a method by which a transparent electrode layer 211 may be conformally and quickly formed on a plurality of nanostructure semiconductor light-emitting units shown in FIGS. 1A and 1B.

When the low temperature liquid phase deposition is used, the transparent electrode layer 211 is quickly formed by using a material in a liquid phase, and the transparent electrode layer may be conformally formed in dense areas having a plurality of semiconductor light-emitting units 110 with high aspect ratios. Also, during the low temperature liquid phase deposition, speed of forming the transparent electrode layer 211 may be adjusted by adjusting the concentration of a material that is included in the transparent electrode layer 211. In addition, during the low temperature liquid phase deposition, an additive may be injected to change electric characteristics of the transparent electrode layer 211. Also, manufacturing cost may be reduced because the low temperature liquid phase deposition does not require high temperature environment.

In the exemplary embodiments, the material for forming the transparent electrode layer 211 may include metal oxide, for example, zinc oxide (ZnO). In the exemplary embodiment, during the low temperature liquid phase deposition, concentration of zinc and a temperature of solution may be adjusted to conformally grow/deposit a transparent ZnO layer on the semiconductor light-emitting units, and an additive may be added to change electric characteristics of the transparent ZnO layer.

When the LED is manufactured by conformally forming the transparent electrode layer 211 on the semiconductor light-emitting units 110 via the low temperature liquid phase deposition according to an exemplary embodiment, the transparent electrode layer 211, which uniformly supplies current, is formed on the side surfaces and the upper surfaces of the semiconductor light-emitting units 110. Then, light is generated in most areas of the semiconductor light-emitting units 110, thereby maximizing the light emission area of the semiconductor light-emitting units 110. Thus, the light emission efficiency may be improved. Also, manufacturing cost of the LED may be reduced and productivity may be improved.

Hereinafter, a method of manufacturing the LED including the transparent electrode layer 211 that is formed via the temperature liquid phase processing will be described.

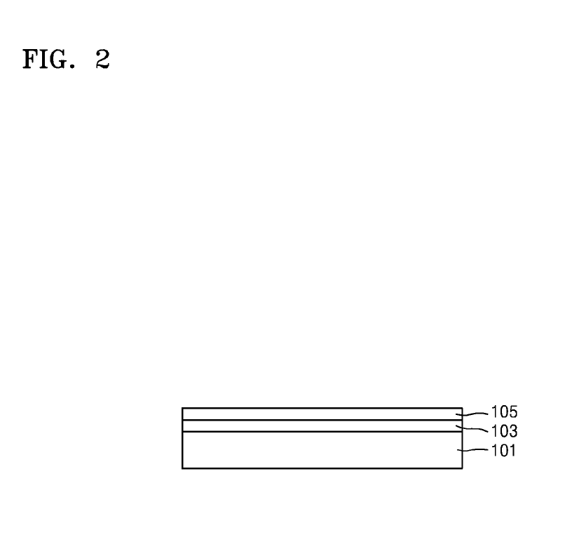

FIGS. 2 to 12 are diagrams for describing the LED manufacturing method according to an exemplary embodiment.

Referring to FIG. 2, the base layer 103 is provided on the substrate 101, and the mask layer 105 is provided on the base layer 103.

The substrate 101 is provided under the semiconductor light-emitting units 110 (see FIG. 1A) and may support the semiconductor light-emitting units 110. The substrate 101 may receive heat generated from the first conductive semiconductor layer 111 (see FIG. 1A) via the base layer 103 and transmit the received heat to an external area. Also, the substrate 101 may have light-transmission characteristics. The substrate 101 may have light-transmission characteristics when the substrate 101 is formed by using a light-transmitting material or formed to a predetermined thickness or less.

An insulative, conductive, or semiconductor substrate may be used as the substrate 101. For example, the substrate 101 may include sapphire (Al₂O₃), gallium nitride (GaN), silicon (Si), germanium (Ge), gallium arsenide (GaAs), zinc oxide (ZnO), silicon germanium (SiGe), silicon carbide (SiC), gallium oxide (Ga₂O₃), lithium gallium oxide (LiGaO₂), lithium aluminum oxide (LiAlO₂), or magnesium aluminum oxide (MgAl₂O₄).

In the exemplary embodiments, a sapphire substrate, a SiC substrate, a silicon substrate, and the like may be mainly used as the substrate 101. Instead of SiC substrates that are relatively expensive, sapphire and silicon substrates are more frequently used.

Before or after forming the semiconductor light-emitting unit 110, the substrate 101 may be completely or partially removed or patterned during an LED manufacturing process to improve optical characteristics or electric characteristics of an LED.

For example, when the substrate 101 is a sapphire substrate, portions of the substrate 101 may be removed by irradiating, with a laser, an interface between the base layer 103 and the substrate 101 via the substrate 101. Alternatively, when the substrate 101 is a silicon substrate or a SiC substrate, portions of the substrate 101 may be removed by polishing or etching.

Alternatively, another supporting substrate may be used to remove the substrate 101. In order to improve light emission efficiency of an LED, a supporting substrate may be attached to an opposite side of the substrate 101 by using reflective metal, or a reflection structure may be inserted between attached layers.

The substrate 101 may be patterned by forming protrusions and depressions or inclined surfaces at a main surface (a front surface or a back surface corresponding to the front surface), or side surfaces of the substrate 101 before or after forming the semiconductor light-emitting units 110 (see FIG. 1A) so as to improve light extraction efficiency. A pattern dimension, for example, a length or width, may be selected within a range of about 5 nm to about 500 μm. As long as light extraction efficiency is improved, patterns may be even or uneven.

The substrate 101 may be a sapphire substrate. Sapphire is a crystal body having Hexa-Rhombo symmetry. The crystal has a lattice constant of 13.001 A in a c-axis direction, and a lattice constant of 4.758 A in an a-axis direction, and has a c(0001) plane, a(1120) plane, and an r(1102) plane. Because the c(0001) plane allows a nitride thin film to be relatively easily grown thereupon and is stable even at high temperatures, a sapphire substrate is frequently utilized as a substrate for nitride growth.

Alternatively, the substrate 101 may be a silicon substrate which is more appropriate for large diameters and cheaper. Mass production may be more convenient by using the silicon substrate. A difference between respective lattice constants of the silicon substrate that has a (111) plane and GaN is about 17%, and a technology for preventing defects caused by the difference between the lattice constants. Because light emission efficiency of an LED is reduced because the silicon substrate absorbs light generated from a GaN-based semiconductor layer, the silicon substrate may be removed if necessary, and a supporting substrate, such as a germanium substrate, a ceramic substrate, or a metal substrate, may be additionally formed and utilized.

The base layer 103 may be formed on the substrate 101. The base layer 103 may be a first conductive semiconductor layer that provides a growth surface for the semiconductor light-emitting units 110.

The mask layer 105 may be formed on the base layer 103. The mask layer 105 may include a dielectric material, for example, SiO₂ or SiNₓ. As described below, the mask layer 105 may be patterned to have opening for growing nano cores of the semiconductor light-emitting units 110.

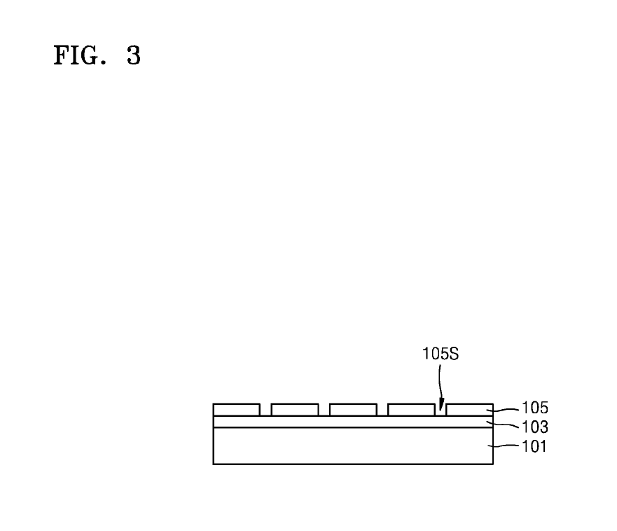

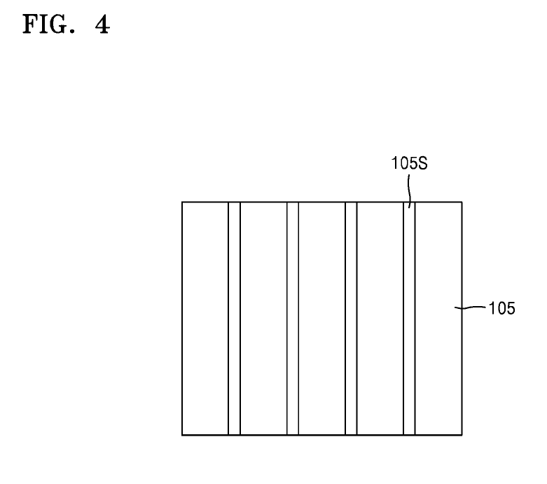

Referring to FIGS. 3 and 4, the mask layer 105 is patterned to have an opening 1055 so as to form the nano cores of the semiconductor light-emitting units 110. FIG. 3 shows a side view of the opening 105S, and FIG. 4 shows a top-down view of the opening 105S.

The opening 105S of the mask layer 105 may be formed by light exposure and etching. The first conductive semiconductor layer 111 (see FIG. 1A) forming the nano cores may be grown based on the base layer 103 via the opening 105S. Because the opening 105S may determine a shape of the semiconductor light-emitting units 110, the opening 105S may be formed with regard to a light emission area and light emission efficiency of the LED.

The opening 105S may be formed as a stripe pattern. A width, length, and height of the stripe pattern may vary according to a size and light emission efficiency of an LED to be manufactured. However, the opening 105S is not limited to a stripe pattern. For example, the opening 105S may be formed as a mesa pattern.

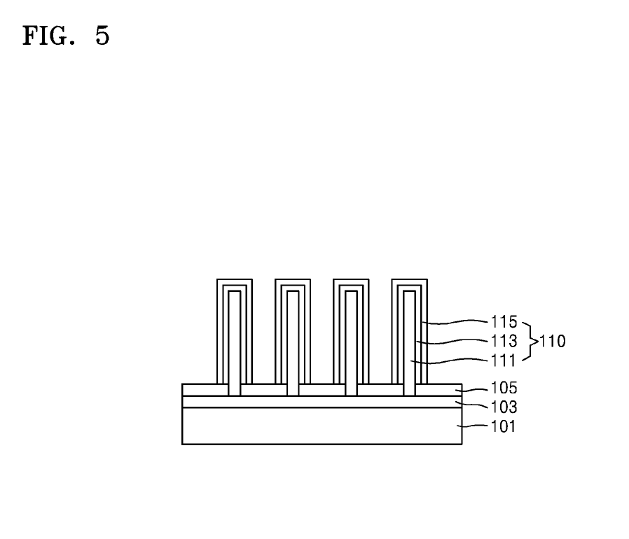

Referring to FIG. 5, the semiconductor light-emitting units 110 forming the nano cores may be formed by selectively growing the first conductive semiconductor layer 111 by using the mask layer 105 having the opening 105S (see FIG. 3), and the active layer 113 and the second conductive semiconductor layer 115 may be formed on surfaces of the nano cores as a shell. Thus, the semiconductor light-emitting units 110 may have a core-shell structure including the nano cores, which are formed from the first conductive semiconductor layer 111, and the shell, which is formed of the active layer 113 that covers side surfaces and upper surfaces of the nano cores and the second conductive semiconductor layer 115 that covers side surfaces and upper surfaces of the active layer 113. Respective widths, lengths, heights, elements, or doping concentrations of the semiconductor light-emitting units 110 may vary so that a single LED emits light with at least two different wavelengths. White light may be provided by the LED by appropriately adjusting light with different wavelengths, without using a phosphor. Also, various colors of light or white light with different color temperatures may be provided by combining an LED including the semiconductor light-emitting units 110 with another LED or combining wavelength conversion materials such as phosphors.

In exemplary embodiments, the first conductive semiconductor layer 111 may include an n-type GaN, and the second conductive semiconductor layer 115 may include a p-type GaN. However, the exemplary embodiments are not limited thereto, and the first and the second conductive semiconductor layers 111 and 115 may include other semiconductor materials so that light with desired wavelength is emitted.

While growing a GaN-based compound semiconductor on the substrate 101, the GaN-based compound semiconductor is formed an n-type or a p-type by supplying impurity gas when necessary. A well-known example of an n-type impurity includes silicon (Si). Examples of a p-type impurity include zinc (Zn), cadmium (Cd), beryllium (Be), manganese (Mn), calcium (Ca), and barium (B a). In general, Mn or Zn may be used.

The active layer 113 between the first conductive semiconductor layer 111 and the second conductive semiconductor layer 115 may have a multi-quantum well (MQW) structure in which quantum well layers and quantum barrier layers are alternately stacked. In the case of a nitride-based compound semiconductor, a GaN/InGaN structure may be used. The active layer 113 may have a single quantum well (SQW) structure.

The semiconductor light-emitting units 110 may have nano-structures. Each of the nano-structures may have an aspect ratio of 10:1 or greater. When using a method of the related art, it may be difficult to conformally form a transparent electrode on the side surfaces and the upper surfaces of the semiconductor light-emitting units 110, and simultaneously, cover an upper surface of the mask layer 105 between the semiconductor light-emitting units 110.

According to the exemplary embodiments, the semiconductor light-emitting units 110 have the same widths, lengths, and height. However, the exemplary embodiments are not limited thereto, and the semiconductor light-emitting units 110 may have different widths, lengths, and heights. Also, the semiconductor light-emitting units 110 may be arranged with uniform or different distances in between. That is, the semiconductor light-emitting units 110 may be formed in various manners according to a specific purpose of using the LED.

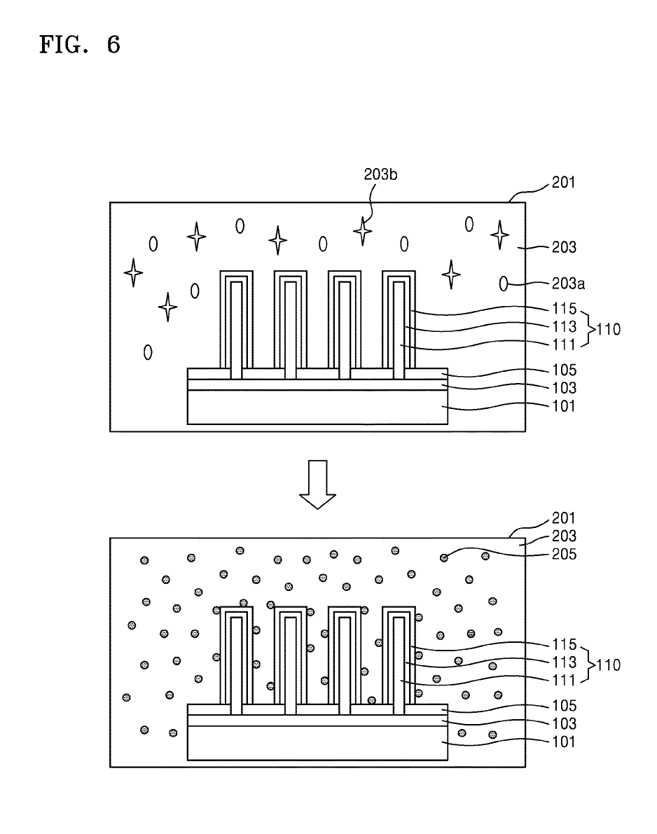

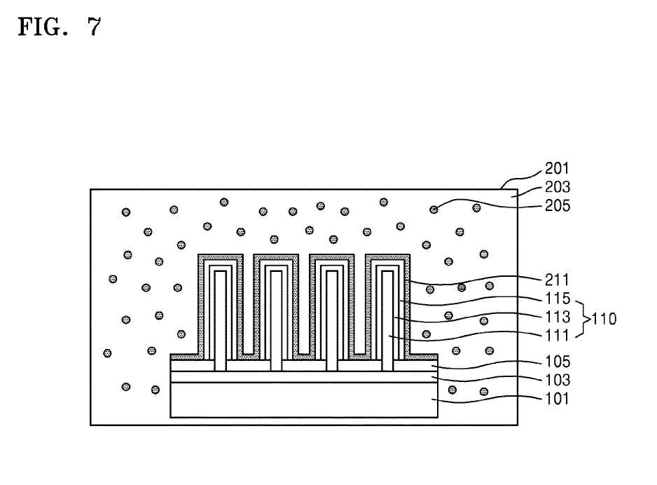

Referring to FIGS. 6 and 7, the low temperature liquid phase deposition is performed to conformally form the transparent electrode on the side surfaces and the upper surfaces of the semiconductor light-emitting units 110.

According to an exemplary embodiment, a buffer layer may be selectively formed on the upper surfaces of the semiconductor light-emitting units 110 and the upper surface of mask layer 105. A material of the buffer layer may include, but is not limited to, Zn, silver (Ag), ZnO, GaN, or titanium nitride (TiN).

For example, when the second conductive semiconductor layer 115 is formed as, for example, a p-type GaN layer, the second conductive semiconductor layer 115 may function as a buffer layer. In the exemplary embodiment, the second conductive semiconductor layer 115 functions as a buffer layer, allowing nucleus growth of ZnO on an aqueous solution 203. Vertical orientation of ZnO to be grown may be determined based on crystallizability of the buffer layer.

The substrate 101, including the semiconductor light-emitting units 110 on which the buffer layer is selectively formed, is dipped into a chamber 201 that contains the aqueous solution 203 containing metal salt 203a and an alkaline ligand compound 203b, for example, the aqueous solution 203 containing zinc salt corresponding to the metal salt 203a and ammonia corresponding to the alkaline ligand compound 203b. The zinc salt in the aqueous solution 203 is generated by combining zinc ions and anions and may be used without limitations. Examples of zinc salt include, but are not limited to, zinc nitrate (Zn(NO₃)₂), zinc sulfate (Zn(SO₄)₂), zinc chloride (ZnCl₂), zinc acetate (Zn(C₂H₃O₂)₂), or a compound thereof. An amount of zinc salt in the aqueous solution 203 may vary according to conditions, and may be within a range of about 0.1 mM to about 1000 mM. When the amount of zinc salt is less than about 0.1 mM, adjusting the amount of zinc salt may be difficult and a zinc oxide layer 211 may not grow or may grow slowly. When the amount of zinc salt is greater than about 1000 mM, an amount of ammonia for adjusting pH of the aqueous solution 203 may increase, and consumption of a source for growing the zinc oxide layer 211 may increase, which thus may cause difficulty in adjusting a thickness of the zinc oxide layer 211.

Different amounts of ammonia may be contained in the aqueous solution 203 according to the amount of zinc salt. Because pH of the aqueous solution 203 increases as more ammonia is added, ammonia may be added such that the aqueous solution 203 has an appropriate level of pH. Ammonia may be added such that pH of the aqueous solution 203 is about 10 to about 12. When the pH of the aqueous solution 203 is less than about 10, the amount of a source that is dipped in liquid phase may increase due to homogeneous nucleation, and thus, a large amount of the source may be unintentionally used. When pH of the aqueous solution 203 is greater than about 12, homogenous nucleation is blocked and the amount of a source dipped in liquid phase may decrease, but this may also block heterogeneous nucleation and may hinder the growth of the zinc oxide layer 211. Deionized water may be used as a base of the aqueous solution 203.

The aqueous solution 203 is heated, and the zinc oxide layer 211 is grown on the semiconductor light-emitting units 110. The buffer layers of the semiconductor light-emitting units 110 may be grown by hydrothermal synthesis. In the related art, hydrothermal synthesis corresponds to a technique of crystallizing an inorganic oxide into an inorganic oxide with low solubility by using the aqueous solution 203 in a supercritical phase or a subcritical phase. According to this technique, high purity monocrystal oxide with a uniform particle size distribution may be synthesized by performing a simple process.

A heating temperature of the aqueous solution 203 may be about 40° C. to about 200° C. When the heating temperature is less than about 40° C., a decomposition reaction may not occur in a zinc-ammonium complex compound and may thus hinder the growth of the zinc oxide layer 211. When the heating temperature is greater than about 200° C., air pressure in the chamber 201 may excessively increase and a high pressure chamber may be required, which may change the growth mechanism. Also, a heating time of the aqueous solution 203 may be about 1 hour to about 24 hours. When the heating time is less than about 1 hour, reaction to the hydrothermal synthesis may hardly occur. When the heating time is greater than about 24, the source may be exhausted and reaction may no longer occur, which may be non-economical.

Processes of forming the zinc oxide layer 211 in the aqueous solution 203 will be further described below.

In an initial state of the aqueous solution 203, Zn²⁺ ions, which are generated as zinc salt melts, exist. Then, ammonia is added, and thus, a complex compound 205 is formed as Zn(NH₃)₄²⁺ (Formula 1). When the aqueous solution 203 is heated according to hydrothermal synthesis, ZnO is formed (Formula 2).

Zn2++4NH3 [symbol] Zn(NH3)42+ Formula 1:

Zn(NH3)42++2OH—→ZnO+4NH3+H₂O Formula 2:

The reaction of Formula 1 is a reversible reaction. Accordingly, because reaction speed may be controlled by adjusting stability of the complex compound 205 having the form of Zn(NH₃)₄²⁺ by changing a ratio of Zn²⁺ ions to ammonia. Thus, growing speed of the transparent electrode layer 211 (or the zinc oxide layer) may be adjusted. Also, homogeneous nucleation in a liquid phase may be prevented by increasing the amount of ammonia, which may thus prevent zinc source from being consumed by precipitation. Therefore, the zinc oxide layer 211 may be grown efficiently by only using a small amount of the zinc source.

Also, a surfactant may be added to the aqueous solution 203 so that the aqueous solution 203 may easily penetrate through the semiconductor light-emitting units 110.

Examples of the surfactant may include a nonionic surfactant, a cationic surfactant, an anionic surfactant, and an amphoteric surfactant.

Examples of the non-ionic surfactant may include polyoxyethylene alkyl ether such as polyoxyethylene lauryl ether and polyoxyethylene stearyl ether, polyoxyethylene alkyl phenyl ether such as polyoxyethylene octylphenyl ether and polyoxyethylene nonylphenyl ether, sorbitan higher fatty acid ester such as sorbitan monolaurate, sorbitan monostearate, and sorbitan trioleate, polyoxyethylene sorbitan higher fatty acid ester such as polyoxyethylene sorbitan monolaurate, polyoxyethylene higher fatty acid ester such as polyoxyethylene monolaurate and polyoxyethylene monostearate, glycerin higher fatty acid ester such as oleic acid monoglyceride and stearic acid monoglyceride, polyoxyalkylene such as polyoxyethylene, polyoxypropylene, and polyoxybuthylene, and a block copolymer thereof.

Examples of the cationic surfactant may include alkyltrimethylammonium chloride, dialkyldimethlylammonium chloride, benzalkonium chloride, and alkyldimethylammonium ethosulfate.

Examples of the anionic surfactant may include lauric acid sodium, oleic acid sodium, N-acyl-N-methylglycine sodium salt, carboxylic acid sodium such as polyoxyethylene lauryl ether carboxylic acid sodium, sulfonic acid salt such as dodecylbenzene sulfonic acid sodium, dialkyl sulfosuccinic acid ester salt, and dimethyl-5-sulfoisophthalate sodium salt, sulfuric acid ester salt such as lauryl sodium sulfate, polyoxyethylene lauryl ether sodium sulfate, and polyoxyethylene nonylphenyl ether sodium sulfate, and phosphoric acid ester salt such as polyoxyethylene lauryl sodium phosphate and polyoxyethylene nonylphenyl ether sodium phosphate.

Examples of the amphoteric surfactant may include carboxybetaine surfactant, aminocarboxylic acid salt, imidazolium betaine, lecithin, and alkylamine oxide.

About 0.1 wt % to about 5 wt % of the surfactant may be added, based on the weight of the aqueous solution 203.

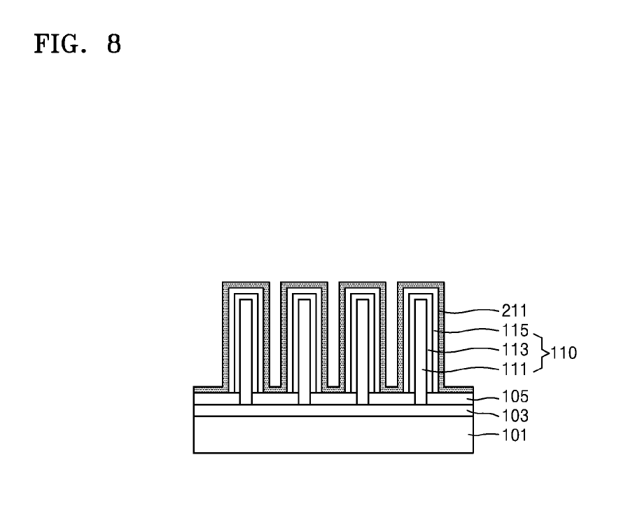

Referring to FIG. 8, the transparent electrode layer 211 is conformally formed on the semiconductor light-emitting units 110 by the low temperature liquid phase deposition. After the low temperature liquid phase deposition, impurities on an outer surface of the transparent electrode layer 211 are primarily removed by drying and cleaning.

A step coverage of the transparent electrode layer 211 may be about 70% or above. That is, a ratio of a thickness of the thickest portion of the transparent electrode layer 211 to a thickness of the thinnest portion of the transparent electrode layer 211 may be about 70% or greater. For example, if the thickness of the thickest portion of the transparent electrode layer 211 is 10 nm, the thickness of the thinnest portion of the transparent electrode layer 211 is between 7 nm to 10 nm. The transparent electrode layer 211 may be formed between the highly dense arrangement of nano-sized semiconductor light-emitting units 110 by low temperature liquid phase deposition.

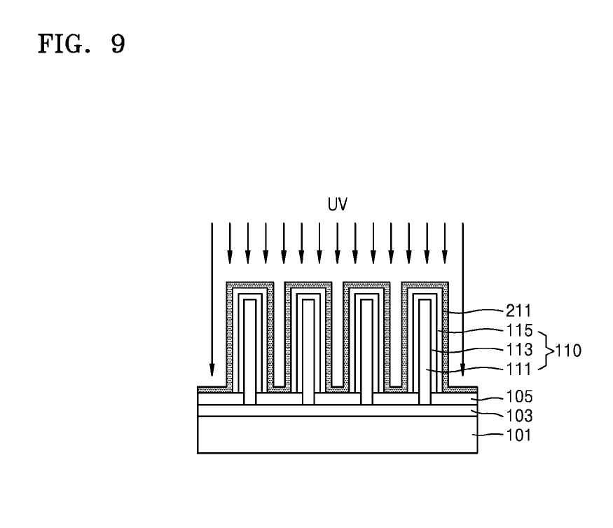

Referring to FIG. 9, ultraviolet rays are irradiated onto the transparent electrode layer 211. When the transparent electrode layer 211 is a zinc oxide layer, the ultraviolet rays may secondarily remove impurities, such as organic salt, on the zinc oxide layer according to a method of forming the zinc oxide layer (i.e., the transparent electrode layer 211). When most of the impurities are removed by the cleaning process above, irradiation of ultraviolet rays may be omitted.

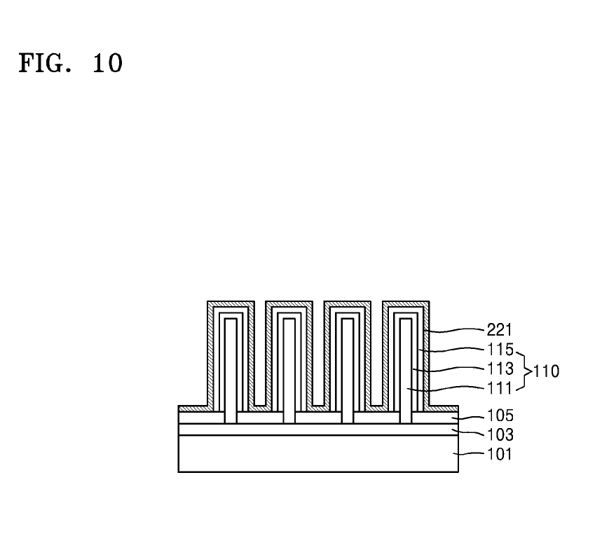

FIG. 10 shows a transparent electrode layer 221, of which impurities are removed by irradiating the transparent electrode layer 221 with ultraviolet rays. The transparent electrode layer 221 may uniformly cover side surfaces and upper surfaces of the second conductive semiconductor layer 115 and stably supply current to the semiconductor light-emitting units 110. Thus, the light emission area of the LED may be enlarged and increase light emission efficiency.

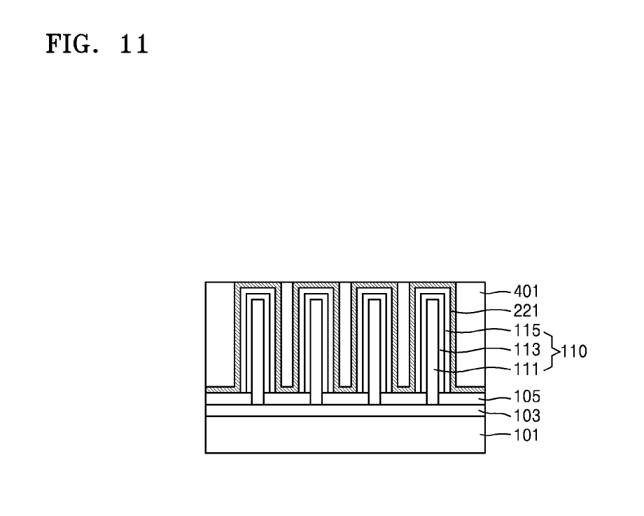

Referring to FIG. 11, a filler 401 may fill spaces between the plurality of semiconductor light-emitting units 110. The filler 401 may structurally stabilize semiconductor light-emitting units 110. The filler 401 may be formed by using a transparent material such as SiO₂, but the examplary embodiment of the filler 401 is not limited thereto.

The filler 401 may include a wavelength conversion material. Wavelengths of light generated by the semiconductor light-emitting units 110 may change as the light passes through the filler 401. The filler 401 may include a first filler and a second filler.

In an exemplary embodiment, the semiconductor light-emitting units 110, which have a nanostructure stripe pattern and emit blue light, may be formed on the substrate 101, and the semiconductor light-emitting units 110 may be arranged at specified intervals. A first red wavelength conversion filler may be formed in some areas between the semiconductor light-emitting units 110, and a second green wavelength conversion filer may be formed in the remaining areas between the semiconductor light-emitting units 110. In this case, the first filler may convert blue light emitted by the semiconductor light-emitting units 110 into red light, and the second filler may convert blue light emitted by the semiconductor light-emitting units 110 into green light. The red light, green light, and blue light emitted by the semiconductor light-emitting units 110 may be combined, and thus, white light having a high color rendering index (CRI) may be output.

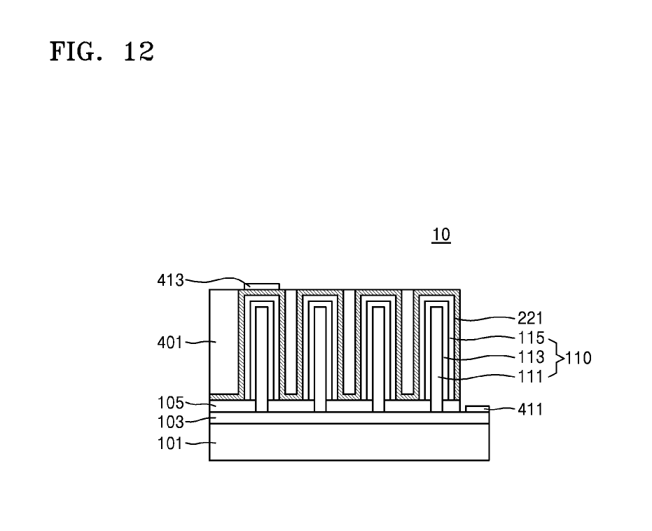

Referring to FIG. 12, the filler 401, the transparent electrode layer 221, and the mask layer 105 may be patterned to expose a portion of the base layer 103, and then, a first electrode 411 connected to the base layer 103 and a second electrode 413 connected to the transparent electrode layer 221 may be formed. The first electrode 411 may be electrically connected to the first conductive semiconductor layer 111 via the base layer 103, and the second electrode 413 may form an ohmic contact with the second conductive semiconductor layer 115. The first electrode 411 and the second electrode 413 may have a single layer or multiple layers of conductive materials including any one of, for example, Ag, aluminum (Al), nickel (Ni), chrome (Cr), and a transparent conductive oxide (TCO) by depositing or sputtering. The first electrode 411 and the second electrode 413 may be arranged in the same direction. Accordingly, an LED 10 including the first electrode 411 and the second electrode 413 may be manufactured.

According to the LED manufacturing method according to the exemplary embodiment, the transparent electrode layer 221 is conformally formed on the semiconductor light-emitting units 110. Thus, the LED 10 may have improved light emission efficiency, production of the LED 10 may improve, and product defects may decrease.

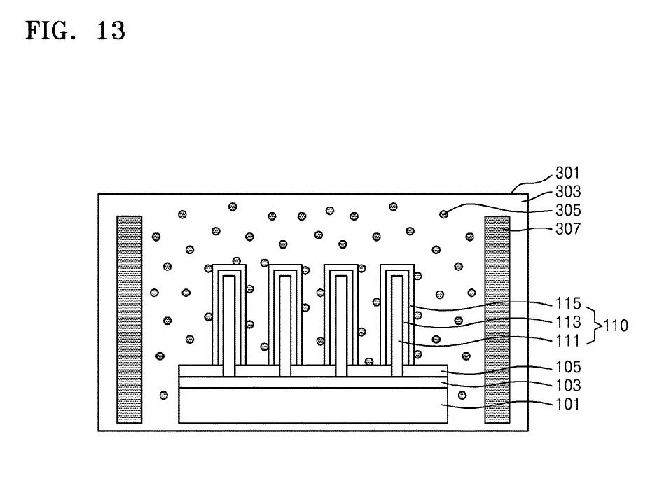

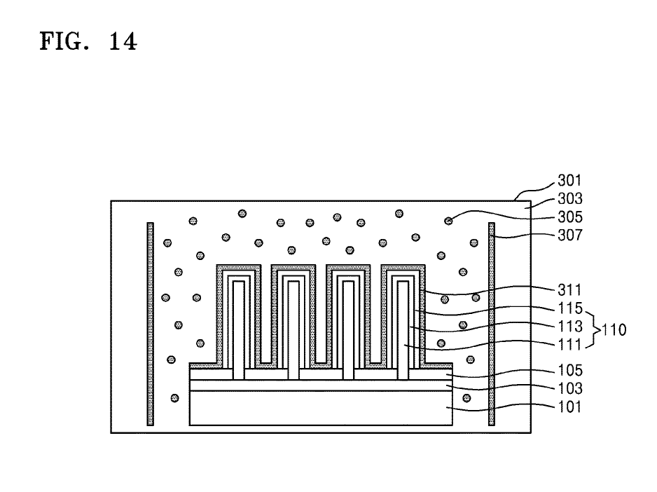

FIGS. 13 and 14 are diagrams for describing forming of a transparent electrode layer via low temperature liquid phase deposition, according to an exemplary embodiment.

Referring to FIGS. 13 and 14, a transparent electrode layer 311 is conformally formed on the side surfaces and the upper surfaces of the semiconductor light-emitting units 110 of FIG. 5 by low temperature liquid phase deposition.

In an exemplary embodiment, a buffer layer may be selectively formed on the upper surfaces of the semiconductor light-emitting units 110 and the mask layer 105. Because features of the buffer layer have been described above with reference to FIGS. 6 and 7, the description will be omitted herein.

The substrate 101, including the semiconductor light-emitting units 110 on which the buffer layer is selectively formed, is dipped into a chamber 301 that contains an oxidized solution 303 including a metal source, for example, an amide-based solution containing zinc foil.

By oxidizing metal in the oxidized solution 303 containing a ligand such as liquid amine to create a metal-ligand complex compound, a metal oxide may be formed on the side surfaces and the upper surfaces of the semiconductor light-emitting units 110. According to the exemplary embodiment, the metal may be zinc (Zn), and the metal oxide may be zinc oxide (ZnO). A zinc foil 307 may be used as a source of zinc. Zinc ions of the zinc foil 307 may function as a source of a metal-ligand complex compound 305, and conformally form a zinc oxide layer 311 on the side surfaces and the upper surfaces of the semiconductor light-emitting units 110 through oxidation-reduction in an amide-based solution. The transparent electrode layer 311 may correspond to the zinc oxide layer 311.

Because the zinc foil 307 functions as the source of zinc for the zinc oxide layer 311, a size of the zinc foil 307 may be reduced as the process proceeds. That is, when the zinc oxide layer 311 is completely formed, the size of the zinc foil 307 may be smaller than at the beginning of the process.

The oxidized solution 303 may contain a formamide solution, for example, N,N-dimethylformamide or N,N-diethylformamide.

A heating temperature of the oxidized solution 303 may be about 0° C. to about 100° C. When the heating temperature is less than about 0° C., decomposition reaction of the metal-ligand complex compound 305 may not be significant, and the growth of the zinc oxide layer 311 may be excessively slow. When the heating temperature exceeds about 100° C., the growth mechanism may change.

A surfactant may be added to the oxidized solution 303 so that the oxidized solution 303 may easily penetrate through the semiconductor light-emitting units 110. This is the same as the exemplary embodiment described above with reference to FIGS. 6 and 7, and the description thereof will be omitted.

A manufacturing time may be adjusted such that a thickness of the zinc oxide layer 311 is about 10 nm to about 30 nm. However, the manufacturing time is not limited thereto, and may be determined based on the respective widths, lengths, and heights of the semiconductor light-emitting units 110.

After conformally forming the zinc oxide layer 311 on the side surfaces and the upper surfaces of the semiconductor light-emitting units 110 via low temperature liquid phase deposition, the operations described with reference to FIGS. 8 to 12 may be performed to thus manufacture the LED.

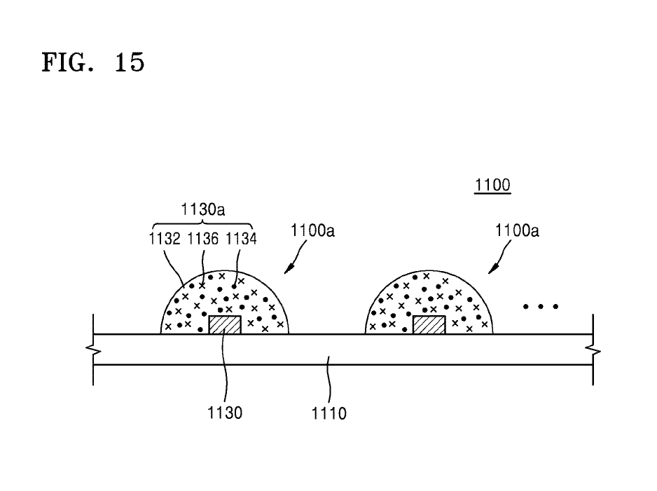

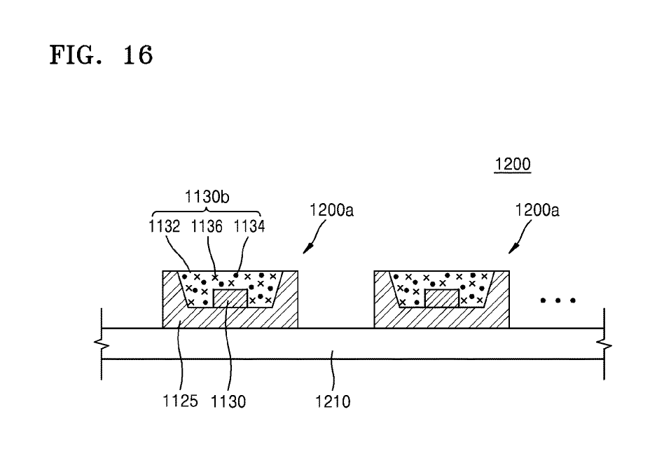

FIGS. 15 and 16 are cross-sectional views of a white light source module including an LED manufactured by using an LED manufacturing method according to an exemplary embodiment.

Referring to FIG. 15, a light source module 1100 for an LCD backlight may include a circuit board 1110 and an array of a plurality of white light-emitting devices 1100a mounted on the circuit board 1110. Conductive patterns connected to the white light-emitting devices 1100a may be formed on the circuit board 1110.

Each of the white light-emitting devices 1100a may be configured such that a light-emitting device 1130 configured to emit blue light is directly mounted on the circuit board 1110 by using a chip on board (COB) method. The light-emitting device 1130 may be the LED 10 (see FIG. 12) manufactured by using the LED manufacturing method according to the above-described exemplary embodiments. Each of the white light-emitting devices 1100a may exhibit a wide orientation angle because a wavelength conversion unit (wavelength conversion layer) 1130a is formed to have a semi-spherical shape with a lens function. The wide orientation angle may contribute to reducing a thickness or a width of an LCD display.

Referring to FIG. 16, a light source module 1200 for an LCD backlight may include a circuit board 1210 and an array of a plurality of white light-emitting devices 1200a mounted on the circuit board 1210. Each of the white light-emitting devices 1200a may include a blue light-emitting device 1130 mounted in a reflection cup of a package body 1125, and a wavelength conversion unit 1130b that encapsulates the light-emitting device 1130. The light-emitting device 1130 may be the LED 10 (see FIG. 12) manufactured by using the LED manufacturing method according to the above-described exemplary embodiments.

If necessary, the wavelength conversion units 1130a and 1130b may include wavelength conversion materials 1132, 1134, and 1136 such as phosphors and/or quantum dots. The wavelength conversion materials will be described below.

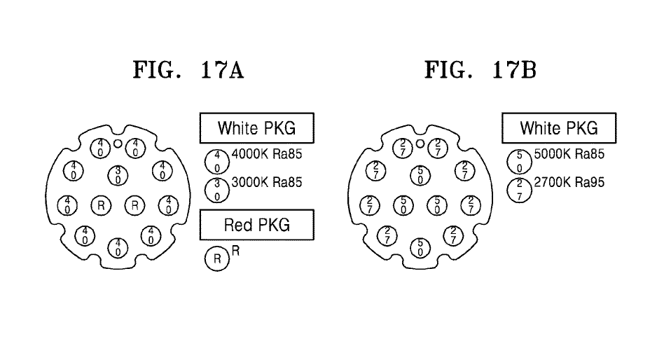

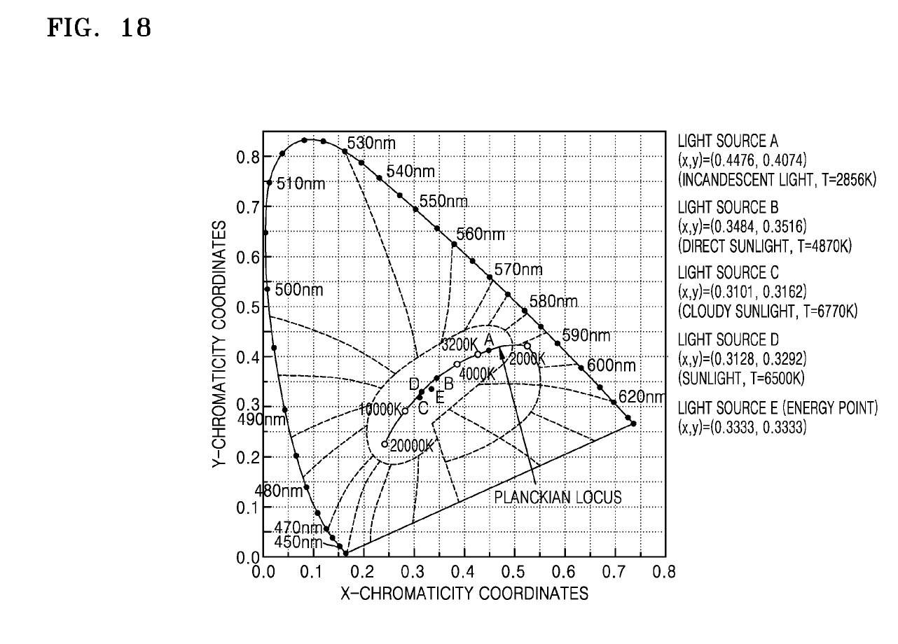

FIGS. 17A and 17B are cross-sectional views of a white light source module, which is adoptable in a lighting device as the LED 10 (see FIG. 12) manufactured by using the LED manufacturing method according to an exemplary embodiment. FIG. 18 is a CIE chromaticity diagram showing a perfect radiator spectrum that is usable for the LED 10 (see FIG. 12) manufactured by using the LED manufacturing method according to an exemplary embodiment.

In an exemplary embodiment, each of light source modules shown in FIGS. 17A and 17B may include a plurality of LED packages 30, 40, R, 27, and 50 mounted on a circuit board. The LED packages 30, 40, R, 27, and 50 may be the LED 10 (see FIG. 12) manufactured by using the LED manufacturing method according to the above-described exemplary embodiments. The LED packages mounted on a single light source module may be the same type of packages that generate light having the same wavelength. However, as in the exemplary embodiment, the LED packages may be different types of packages that generate light having different wavelengths.

Referring to FIG. 17A, the white light source module may be a combination of the white LED packages 40 and 30 having a color temperature of 4,000K and 3,000K and the red LED package R. The white light source module may adjust a color temperature in the range of about 3,000K and about 4,000K and provide white light having a CRI Ra of about 85 to about 100.

According to another exemplary embodiment, the white light source module includes only white LED packages, but some packages may include white light having different color temperatures. For example, as illustrated in FIG. 17B, it is possible to adjust a color temperature in the range of about 2,700K to about 5,000K and provide white light having a CRI Ra of about 85 to about 99 by combining the white LED package 27 having a color temperature of about 2,700K and the white LED package 50 having a color temperature of about 5,000K. The number of LED packages for each color temperature may be changed according to a basic color temperature setting value. For example, in a lighting apparatus, of which a basic color temperature setting value is around a color temperature of 4,000K, the number of packages corresponding to a color temperature of 4,000K may be larger than the number of packages corresponding to a color temperature of 3,000K or the number of red LED packages.

As such, the different types of LED packages may include an LED package that emits white light by combining a yellow, green, red, or orange-color phosphor with a blue LED. The LED package that emits white light may be configured to include at least one of a violet LED, a blue LED, a green LED, a red LED, and an infrared LED, and thus adjust a color temperature and a CRI of white light.

The single LED package may determine light of a desired color according to a wavelength of an LED chip and a type and a combination ratio of phosphors. In the case of the white light, the color temperature and the CRI may be adjusted.

For example, when the LED chip emits blue light, the LED package including at least one of the yellow, green, and red phosphors may be configured to emit white light having various color temperatures according to a combination ratio of the phosphors. Unlike this, the LED package, in which the green or red phosphor is applied to the blue LED chip, may be configured to emit green or red light. The color temperature and the CRI of the white light may be adjusted by combining the LED package emitting the white light and the LED package emitting the green or red light. In addition, the LED package may include at least one of LEDs emitting the violet, blue, green, red, and infrared light

In this case, the lighting apparatus may adjust the CRI to a photovoltaic level in a sodium (Na) lamp. In addition, the lighting apparatus may generate a variety of white light having a color temperature of about 1,500K to about 20,000K. When necessary, the lighting apparatus may adjust an illumination color according to a surrounding atmosphere or a mood by generating infrared light or visible light such as violet, blue, green, red, or orange color light. In addition, the lighting apparatus may generate light having a specific wavelength so as to promote the growth of plants.

The white light, which is generated by the combination of the yellow, green and red phosphors and/or the green and red LEDs in the blue LED has two or more peak wavelengths. As illustrated in FIG. 18, (x, y) coordinates of the white light in the CIE 1931 coordinate system may be positioned within a line segment connecting coordinates (0.4476, 0.4074), (0.3484, 0.3516), (0.3101, 0.3162), (0.3128, 0.3292), and (0.3333, 0.3333). Alternatively, the (x, y) coordinates may be positioned in a region surrounded by the line segment and a black-body radiator spectrum. The color temperature of the white light is in the range of about 1,500K to about 20,000K. In FIG. 18, because the white light around point E (0.3333, 0.3333) under the black-body radiator spectrum (Planckian locus) is relatively weak in the light of the yellow-based component, it may be used as an illumination light source in a region in which a user may have a more vivid or fresh feeling than naked eyes. Therefore, an illumination product using the white light around point E (0.3333, 0.3333) under the black-body radiator spectrum (Planckian locus) may be suitable as lighting for shopping malls that sell groceries and clothes.

On the other hand, various materials, such as phosphors and/or quantum dots, may be used as a material for converting a wavelength of light emitted by the semiconductor LED.

The phosphor may have the following empirical formulas and colors.

Oxide-based: yellow and green color Y₃Al₅O₁₂:Ce, Tb₃Al₅O₁₂:Ce, Lu₃Al₅O₁₂:Ce

Silicate-based: yellow color and green color (Ba,Sr)₂SiO₄:Eu, yellow color and orange color (Ba,Sr)₃SiO₅:Ce

Nitride-based: green color β-SiAlON:Eu, yellow color La₃Si₆O₁₁:Ce, orange color α-SiAlON:Eu, red color CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≦x≦3, 0<z<0.3, 0<y≦4) Formula (1)

In Formula (1) of Table 1, Ln may be at least one element selected from the group consisting of group Ma elements and rare-earth elements, and M may be at least one element selected from the group consisting of calcium (Ca), barium (Ba), strontium (Sr), and Mg.

Fluoride-based: KSF-based red color K₂SiF₆:Mn⁴⁺, K₂TiF₆:Mn⁴⁺, NaYF₄:Mn⁴⁺, NaGdF₄:Mn⁴⁺, K₃ SiF₇:Mn⁴⁺.

The composition of the phosphor needs to basically conform with stoichiometry, and the respective elements may be substituted by other elements included in the respective groups of the periodic table. For example, strontium (Sr) may be substituted by at least one selected from the group consisting of Ba, Ca, and Mg of alkaline-earth group II, and Y may be substituted by at least one selected from the group terbium (Tb), lutetium (Lu), scandium (Sc), and gadolinium (Gd). In addition, europium (Eu), which is an activator, may be substituted by at least one selected from the group consisting of cerium (Ce), terbium (Tb), praseodymium (Pr), erbium (Er), and ytterbium (Yb) according to a desired energy level. The activator may be applied solely or a sub activator may be additionally applied for characteristic modification.

In particular, in order to improve the reliability at a high temperature and high humidity, the fluoride-based red phosphor may be coated with a Mn-free fluoride material or may further include an organic coating on the surface of the phosphor or the coated surface of the Mn-free fluoride material. In the case of the fluoride-based red phosphor, it is possible to implement a narrow half-width of about 40 nm or less unlike other phosphors. Thus, the fluoride-based red phosphor may be applied to a high-resolution TV such as UHD TV.

Table 1 below shows types of phosphors according to applications of a white LED using a blue LED chip (about 440 nm to about 460 nm) or a UV LED chip (about 380 nm to about 440 nm).

TABLE 1

| Usage | Phosphor |
|---|---|
| LED TV BLU | β-SiAlON:Eu²⁺ |
| | (Ca,Sr)AlSiN₃:Eu²⁺ |
| | La₃Si₆N₁₁:Ce³⁺ |
| | K₂SiF₆:Mn⁴⁺ |
| | SrLiAl₃N₄:Eu |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, |
| | 0 < y ≦ 4) |
| | K₂TiF₆:Mn⁴⁺ |
| | NaYF₄:Mn⁴⁺ |
| | NaGdF₄:Mn⁴⁺ |
| Illumination | Lu₃Al₅O₁₂:Ce³⁺ |
| | Ca-α-SiAlON:Eu²⁺ |
| | La₃Si₆N₁₁:Ce³⁺ |
| | (Ca,Sr)AlSiN₃:Eu²⁺ |
| | Y₃Al₅O₁₂:Ce³⁺ |
| | K₂SiF₆:Mn⁴⁺ |
| | SrLiAl₃N₄:Eu |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, |
| | 0 < y ≦ 4) |
| | K₂TiF₆:Mn⁴⁺ |
| | NaYF₄:Mn⁴⁺ |
| | NaGdF₄:Mn⁴⁺ |
| Side View | Lu₃Al₅O₁₂:Ce³⁺ |
| (Mobile, Note PC) | Ca-α-SiAlON:Eu²⁺ |
| | La₃Si₆N₁₁:Ce³⁺ |
| | (Ca,Sr)AlSiN₃:Eu²⁺ |
| | Y₃Al₅O₁₂:Ce³⁺ |
| | (Sr,Ba,Ca,Mg)₂SiO₄:Eu²⁺ |
| | K₂SiF₆:Mn⁴⁺ |
| | SrLiAl₃N₄:Eu |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, |
| | 0 < y ≦ 4) |
| | K₂TiF₆:Mn⁴⁺ |
| | NaYF₄:Mn⁴⁺ |
| | NaGdF₄:Mn⁴⁺ |
| Electrical | Lu₃Al₅O₁₂:Ce³⁺ |
| Component | Ca-α-SiAlON:Eu²⁺ |
| (Head Lamp, etc.) | La₃Si₆N₁₁:Ce³⁺ |
| | (Ca,Sr)AlSiN₃:Eu²⁺ |
| | Y₃Al₅O₁₂:Ce³⁺ |
| | K₂SiF₆:Mn⁴⁺ |
| | SrLiAl₃N₄:Eu |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, |
| | 0 < y ≦ 4) |
| | K₂TiF₆:Mn⁴⁺ |
| | NaYF₄:Mn⁴⁺ |
| | NaGdF₄:Mn⁴⁺ |

In addition, the wavelength conversion unit may include wavelength conversion materials such as a quantum dot (QD) by substituting phosphors or combining phosphors.

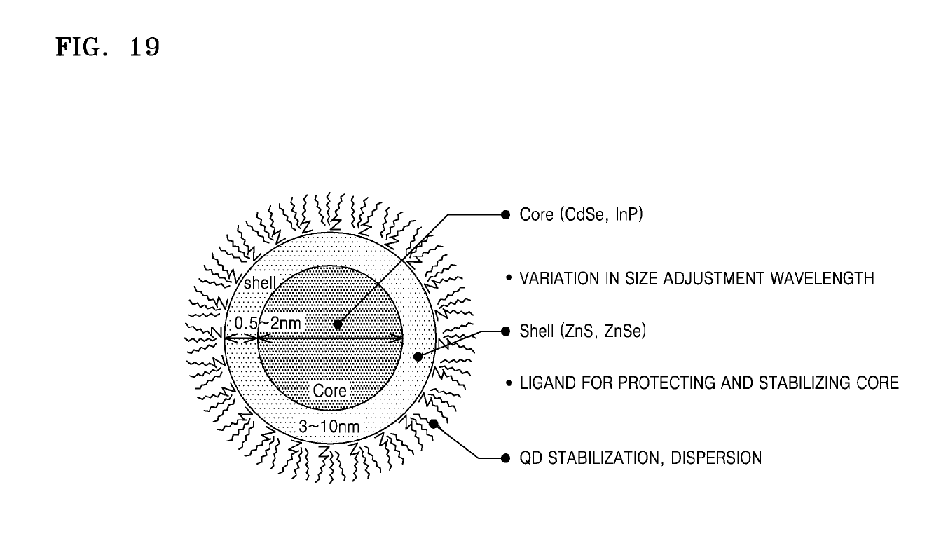

FIG. 19 is a cross-sectional view of a quantum dot as a wavelength conversion material that is usable for the LED 10 (see FIG. 12) manufactured by using the LED manufacturing method according to an exemplary embodiment.

Referring to FIG. 19, the QD may have a core-shell structure using group III-V or II-VI compound semiconductors. For example, QD may have a core such as CdSe or InP and a shell such as ZnS or ZnSe. In addition, the QD may include a ligand for stabilizing the core and the shell. For example, the core may have a diameter of about 1 nm to about 30 nm and specifically about 3 nm to about 10 nm. The shell may have a thickness of about 0.1 nm to about 20 nm and specifically 0.5 nm to about 2 nm.

The QD may implement various colors according to a size. In particular, when the QD is used as a phosphor substitute, the QD may be used as a red or green phosphor. In the case of using the QD, a narrow half-width (for example, about 35 nm) may be implemented.

The wavelength conversion material may be implemented as being contained in an encapsulating material. However, the wavelength conversion material may be previously prepared in a film shape and be attached to a surface of an optical structure such as an LED chip or a light guide plate. In this case, the wavelength conversion material may be easily applied to a desired region in a structure having a uniform thickness.

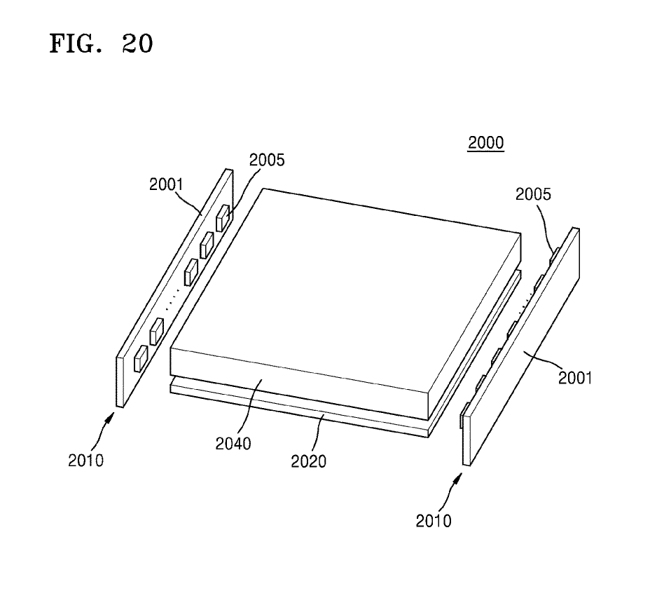

FIG. 20 is a perspective view of a backlight unit including an LED manufactured by using the LED manufacturing method according to an exemplary embodiment.

Referring to FIG. 20, the backlight unit 2000 may include a light guide plate 2040 and light source modules 2010 on both sides of the light guide plate 2040. In addition, the backlight unit 2000 may further include a reflective plate 2020 under the light guide plate 2040. The backlight unit 2000 according to the exemplary embodiment may be an edge-type backlight unit. According to some exemplary embodiments, the light source module 2010 may be provided only one side of the light guide plate 2040 or may be additionally provided on the other side. The light source module 2010 may include a printed circuit board (PCB) 2001 and a plurality of light sources 2005 mounted on the PCB 2001. The light source 2005 may be the LED 10 (see FIG. 12) manufactured by using the LED manufacturing method according to the above-described exemplary embodiments.

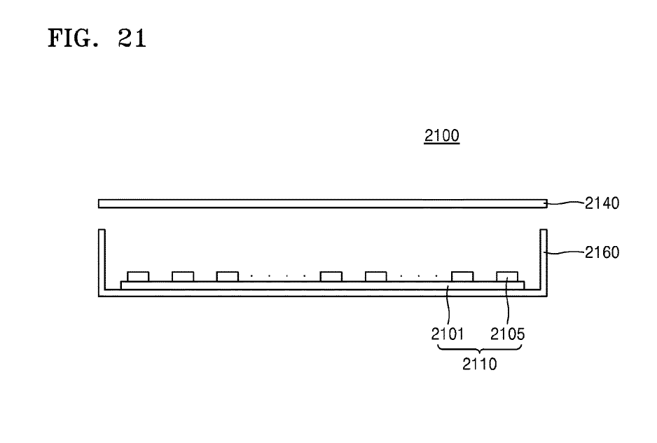

FIG. 21 is a cross-sectional view of a direct-type backlight unit including an LED manufactured by using the LED manufacturing method according to an exemplary embodiment.

Referring to FIG. 21, the backlight unit 2100 may include a light diffusion plate 2140 and a light source module 2110 under the light diffusion plate 2140. In addition, the backlight unit 2100 may further include a bottom case 2160 under the light diffusion plate 2140 to accommodate the light source module 2110. The backlight unit 2100 according to the exemplary embodiment may be a direct-type backlight unit.

The light source module 2110 may include a PCB 2101 and a plurality of light sources 2105 mounted on the PCB 2101. The light source 2105 may be the LED 10 (see FIG. 12) manufactured by using the LED manufacturing method according to the above-described exemplary embodiments.

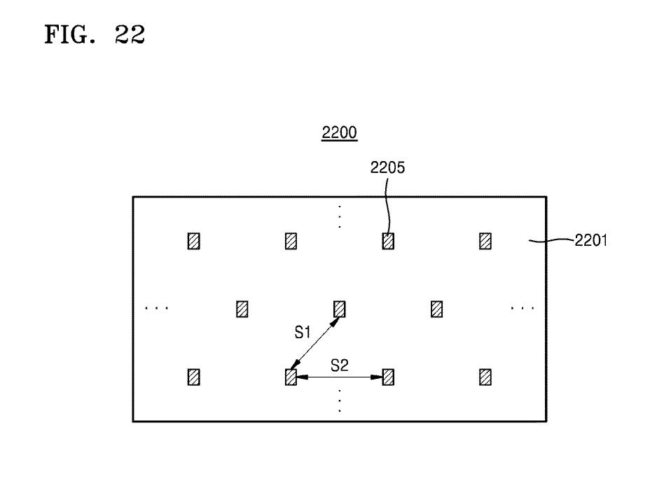

FIG. 22 is a plan view of a backlight unit 2200 including an LED manufactured by using the LED manufacturing method according to an exemplary embodiment.

FIG. 22 illustrates an example of an arrangement of a light source 2205 in a direct-type backlight unit 2200. The light source 2205 may be the LED 10 (see FIG. 12) manufactured by using the LED manufacturing method according to the above-described exemplary embodiments.

The direct-type backlight unit 2200 according to the exemplary embodiment may include a plurality of light sources 2205 arranged on a substrate 2201. The light sources 2205 may be arranged in a matrix form, of which rows and columns are in a zigzag arrangement. A second matrix having the same shape may be arranged in a first matrix in which the plurality of light sources 2205 are arranged in rows and columns on a straight line. It may be understood that the light sources 2205 included in the second matrix are inside a rectangle formed by four adjacent light sources 2205 included in the first matrix.

In the direct-type backlight unit, the arrangement structure and intervals of the first matrix and the second matrix may be different so as to further improve brightness uniformity and optical efficiency thereof. Besides the method of arranging the plurality of light sources, distances Si and S2 between the adjacent light sources may be optimized so as to ensure the brightness uniformity. In this manner, the rows and columns on which the light sources 2205 are arranged may be in a zigzag arrangement, instead of the straight line, thus reducing the number of light sources 2205 by about 15% to about 25% with respect to the same light emission area.

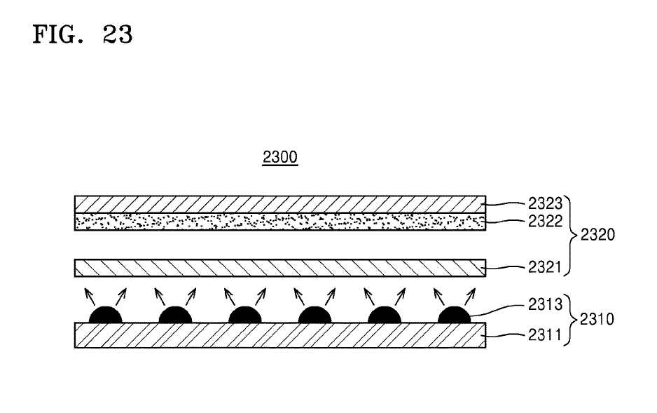

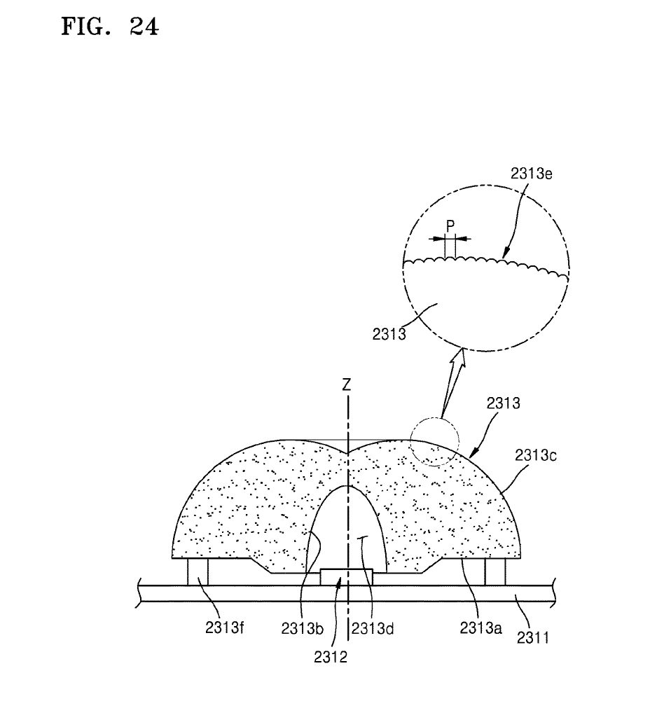

FIG. 23 is a cross-sectional view of a direct-type backlight unit 2300 including an LED manufactured by using the LED manufacturing method according to an exemplary embodiment, and FIG. 24 is an enlarged diagram of a light source module 2310 of FIG. 23.

Referring to FIG. 23, the direct-type backlight unit 2300 according to the exemplary embodiment may include an optical sheet 2320 and a light source module 2310 under the optical sheet 2320. The optical sheet 2320 may include a diffusion sheet 2321, a light concentration sheet 2322, and a protection sheet 2323.

The light source module 2310 may include a circuit board 2311, a plurality of light sources 2312 mounted on the circuit board 2311, and a plurality of optical elements 2313 respectively on the plurality of light sources 2312. The light source 2312 may be the LED 10 (see FIG. 12) manufactured by using the LED manufacturing method according to the above-described exemplary embodiments.

The optical element 2313 may adjust an orientation angle of light through reflection. In particular, a light orientation-angle lens configured to diffuse light of the light source 2312 to a wide region may be used. Because the light source 2312, to which the optical element 2313 is attached, has a wider light distribution, the number of light sources 2312 per the same area may be reduced when the light source module 2310 is used in a backlight or a flat-panel lighting apparatus.

As illustrated in FIG. 24, the optical element 2313 may include a bottom surface 2313a on the light source 2312, an incidence surface 2313b on which the light of the light source 2312 is incident, and an exit surface 2313c from which the light is output. The bottom surface 2313a of the optical element 2313 may have a groove 2313d recessed in a direction of the exit surface 2313c in a center through which an optical axis Z of the light source 2312 passes. The groove 2313d may be defined as an incidence surface 2313b on which the light of the light source 2312 is incident. That is, the incidence surface 2313b may form a surface of the groove 2313d.

The bottom surface 2313a of the optical element 2313 may partially protrude toward the light source 2312 in a central portion connected to the incidence surface 2313b to thereby have a non-planar structure as a whole. That is, unlike a general flat structure, the entire bottom surface 2313a of the optical element 2313 may partially protrude along a periphery of the groove 2313d. A plurality of supports 2313f may be provided on the bottom surface 2313a of the optical element 2313. When the optical element 2313 is mounted on the circuit board 2311, the plurality of supports 2313f may fix and support the optical element 2313.

The exit surface 2313c of the optical element 2313 may protrude upward (a light exit direction) from an edge connected to the bottom surface 2313a in a dome shape, and have an inflection point such that a center through which the optical axis Z passes is concavely recessed toward the groove 2313d. A plurality of concave/convex portions 2313e may be periodically arranged on the exit surface 2313c in a direction of the edge from the optical axis Z. The plurality of concave/convex portions 2313e may have a ring shape corresponding to a horizontal cross-sectional shape of the optical element 2313 and may form a concentric circle from the optical axis Z. The plurality of concave/convex portions 2313e may be radially arranged while forming periodic patterns along the surface of the exit surface 2313c from the center of the optical axis Z.

The plurality of concave/convex portions 2313e may be spaced apart by regular pitches P to form patterns. In this case, the pitch P between the plurality of concave/convex portions 2313e may be in the range of about 0.01 mm to about 0.04 mm. The plurality of concave/convex portions 2313e may offset a difference of performance between the optical elements due to a fine processing error that may occur in the process of manufacturing the optical element 2313, and may improve the uniformity of the light distribution accordingly.

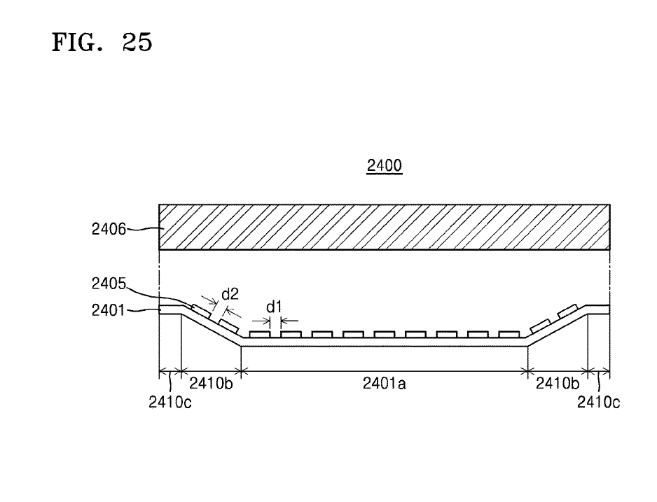

FIG. 25 is a cross-sectional view of a direct-type backlight unit 2400 including an LED manufactured by using the LED manufacturing method according to an exemplary embodiment.

Referring to FIG. 25, the direct-type backlight unit 2400 may include a circuit board 2401, a light source 2405 mounted on the circuit board 2401, and one or more optical sheets 2406 on the light source 2405. The light source 2405 may be a white light-emitting device including a red phosphor. The light source 2405 may be a module mounted on the circuit board 2401. The light source 2405 may be the LED 10 (see FIG. 12) manufactured by using the LED manufacturing method according to the above-described exemplary embodiments.

The circuit board 2401 may have a first flat portion 2401a corresponding to a main region, an inclined portion 2401b arranged around the first flat portion 2401a and bent in at least a portion thereof, and a second flat portion 2401c arranged at an edge of the circuit board 2401 that is an outside of the inclined portion 2401b. The light sources 2405 may be arranged at a first interval d1 on the first flat portion 2401a, and one or more light sources 2405 may also be arranged at a second interval d2 on the inclined portion 2401b. The first interval d1 may be substantially equal to the second interval d2. A width (or a length in a cross-section) of the inclined portion 2401b may be smaller than a width of the first flat portion 2401a and larger than a width of the second flat portion 2401c. In addition, at least one light source 2405 may be arranged on the second flat portion 2401c when necessary.

A slope of the inclined portion 2401b may be appropriately adjusted in the range of greater than 0° and less than 90° with reference to the first flat portion 2401a. Due to such a configuration, the circuit board 2401 may maintain uniform brightness even at the edge of the optical sheet 2406.

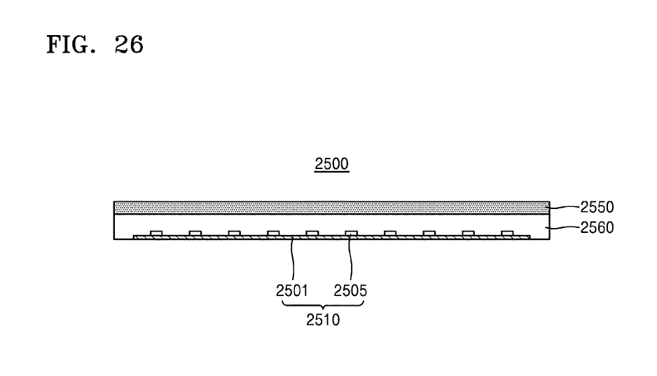

FIGS. 26 to 28 are cross-sectional views of backlight units 2500, 2600, and 2700 including an LED manufactured by using the LED manufacturing method according to an exemplary embodiment;

In the backlight units 2500, 2600, and 2700, wavelength conversion units 2550, 2650, and 2750 are not arranged in light sources 2505, 2605, and 2705. The wavelength conversion units 2550, 2650, and 2750 are arranged in the backlight units 2500, 2600, and 2700 outside the light sources 2505, 2605, and 2705 so as to convert light. The light sources 2505, 2605, and 2705 may be the LED 10 (see FIG. 12) manufactured by using the LED manufacturing method according to the above-described exemplary embodiments.

The backlight unit 2500 of FIG. 26 is a direct-type backlight unit and may include the wavelength conversion unit 2550, a light source module 2510 under the wavelength conversion unit 2550, and a bottom case 2560 accommodating the light source module 2510. In addition, the light source module 2510 may include a PCB 2501 and a plurality of light sources 2505 mounted on the PCB 2501.

In the backlight unit 2500, the wavelength conversion unit 2550 may be on the bottom case 2560. Therefore, at least a part of the light emitted by the light source module 2510 may be wavelength-converted by the wavelength conversion unit 2550. The wavelength conversion unit 2550 may be manufactured as a separate film and may be integrated with a light diffusion plate (not shown).

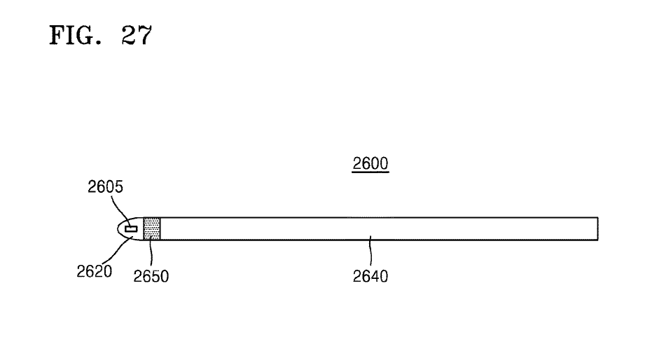

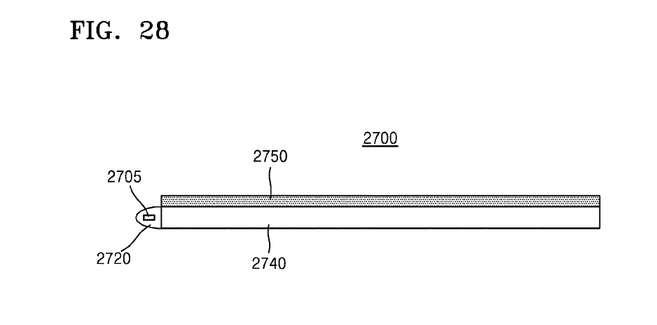

The backlight units 2600 and 2700 of FIGS. 27 and 28 are edge-type backlight units and may include the wavelength conversion unit 2650 and 2750, light guide plates 2640 and 2740, and reflection units 2620 and 2720 and light sources 2605 and 2705 arranged on one side of the light guide plates 2640 and 2740. The light emitted by the light sources 2605 and 2705 may be guided inside the light guide plates 2640 and 2740 by the reflection units 2620 and 2720. In the backlight unit 2600 of FIG. 27, the wavelength conversion unit 2650 may be arranged between the light guide plate 2640 and the light source 2605. In the backlight unit 2700 of FIG. 28, the wavelength conversion unit 2750 may be on a light emission surface of the light guide plate 2740.

The wavelength conversion units 2550, 2650, and 2750 may include typical phosphors. In particular, QD phosphors may be used for supplementing characteristics of QDs vulnerable to moisture or heat from the light source.

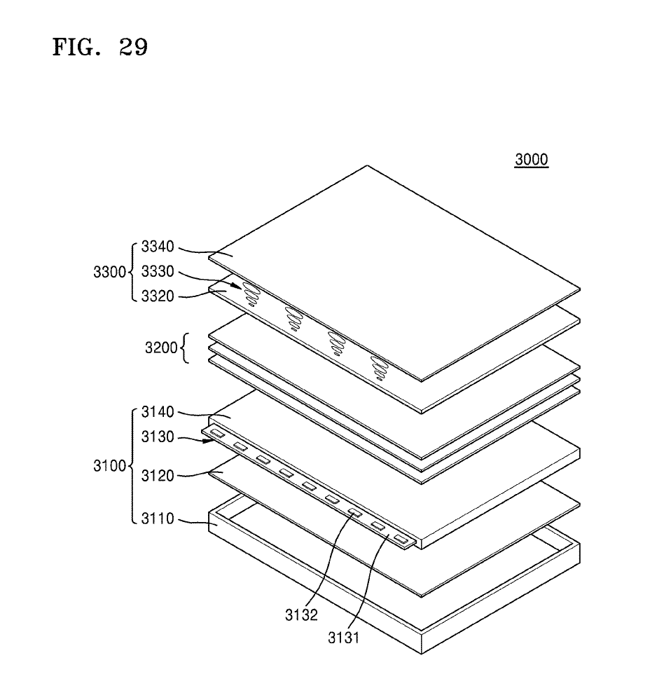

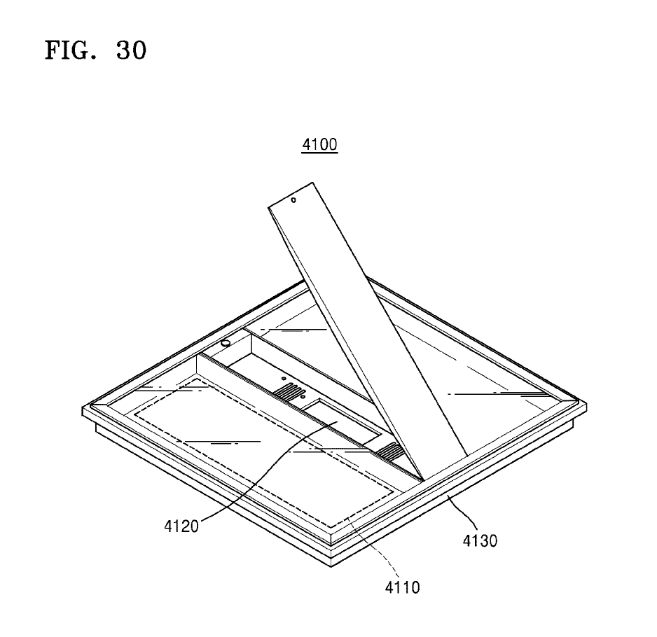

FIG. 29 is an exploded perspective view of a display device 3000 including an LED manufacturing by using the LED manufacturing method according to an exemplary embodiment.

Referring to FIG. 24, the display device 3000 may include a backlight unit 3100, an optical sheet 3200, and a display panel 3300 such as a liquid crystal panel. The backlight unit 3100 may include a bottom case 3110, a reflection plate 3120, a light guide plate 3140, and a light source module 3130 on at least one side of the light guide plate 3140. The light source module 3130 may include a PCB 3131 and a light source 3132.

In particular, the light source 3132 may be a side view type LED mounted on a side adjacent to a light emission surface. The light source 3132 may be the LED 10 (see FIG. 12) manufactured by using the LED manufacturing method according to the above-described exemplary embodiments. The optical sheet 3200 may be between the light guide plate 3140 and the display panel 3300 and may include various types of sheets, such as a diffusion sheet, a prism sheet, or a protection sheet.

The display panel 3300 may display an image by using light emitted from the optical sheet 3200. The display panel 3300 may include an array substrate 3320, a liquid crystal layer 3330, and a color filter substrate 3340. The array substrate 3320 may include pixel electrodes arranged in a matrix form, thin film transistors configured to apply a driving voltage to the pixel electrodes, and signal lines configured to operate the thin film transistors.

The color filter substrate 3340 may include a transparent substrate, a color filter, and a common electrode. The color filter may include filters configured to selectively transmit light having a specific wavelength in white light emitted by the backlight unit 3100. The liquid crystal layer 3330 may be rearranged by an electric field formed between the pixel electrode and the common electrode and adjust an optical transmittance. The light, of which the optical transmittance is adjusted, may display an image while passing through the color filter of the color filter substrate 3340. The display panel 3300 may further include a driving circuit configured to process an image signal.

According to the exemplary embodiment, because the display device 3000 uses the light source 3132 configured to emit blue light, green light, and red light having a relatively small half-width, the emitted light may implement blue, green, and red colors having a high color purity after passing through the color filter substrate 3340.

FIG. 30 is a perspective view of a flat-panel lighting apparatus 4100 including an LED manufacturing by using the LED manufacturing method according to an exemplary embodiment.

Referring to FIG. 25, the flat-panel lighting apparatus 4100 may include a light source module 4110, a power supply 4120, and a housing 4030. The light source module 4110 may include an LED array as a light source. The light source module 4110 may be the LED 10 (see FIG. 12) manufactured by using the LED manufacturing method according to the above-described exemplary embodiments. The power supply 4120 may include an LED driver.

The light source module 4110 may include an LED array and may be formed to have a flat shape as a whole. The LED array may include an LED and a controller configured to store driving information of the LED.

The power supply 4120 may be configured to supply power to the light source module 4110. The housing 4130 may form an accommodation space for accommodating the light source module 4110 and the power supply 4120. The housing 4130 is formed to have a hexahedral shape with one opened side, but is not limited thereto. The light source module 4110 may be arranged to emit light toward the opened side of the housing 4130.

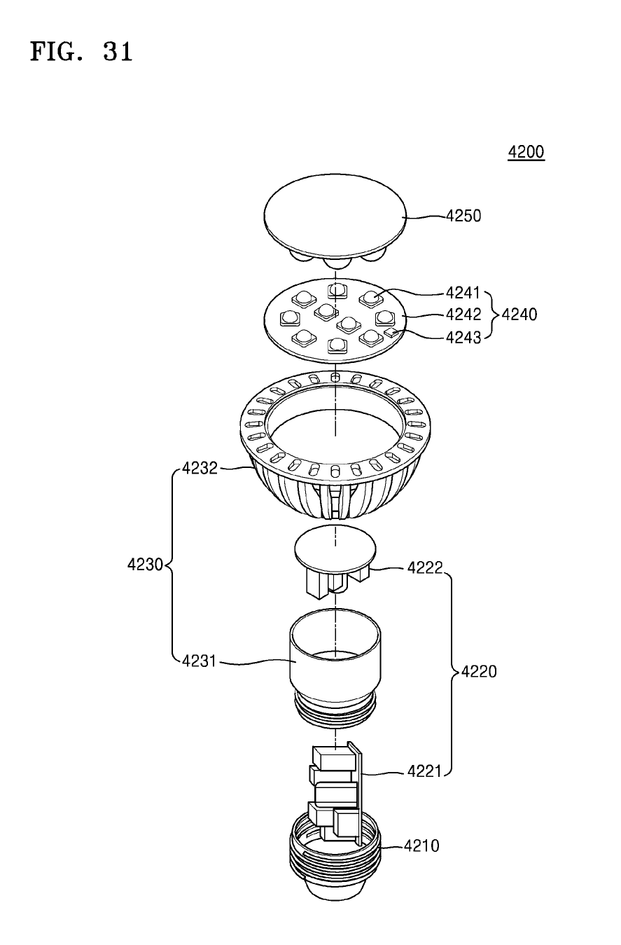

FIG. 31 is an exploded perspective view of a lighting apparatus 4200 including an LED manufacturing by using the LED manufacturing method according to an exemplary embodiment.

Referring to FIG. 31, the lighting apparatus 4200 may include a socket 4210, a power supply 4220, a heat sink 4230, a light source module 4240, and an optical unit 4250. The light source module 4240 may include an LED array, and the power supply 4220 may include an LED driver.

The socket 4210 may be configured to be replaceable with an existing lighting apparatus. Power may be supplied to the lighting apparatus 4200 through the socket 4210.

The power supply 4220 may be dissembled into a first power supply 4221 and a second power supply 4220. The heat sink 4230 may include an internal heat sink 4231 and an external heat sink 4232. The internal heat sink 4231 may be directly connected to the light source module 4240 and/or the power supply 4220. The internal heat sink 4231 may transmit heat to the external heat sink 4232. The optical unit 4250 may include an internal optical unit (not illustrated) and an external optical unit (not illustrated). The optical unit 4250 may be configured to uniformly disperse light emitted by the light source module 4240.

The light source module 4240 may receive power from the power supply 4220 and emit light to the optical unit 4250. The light source module 4240 may include one or more LED packages 4241, a circuit board 4242, and controller 4243. The controller 4243 may store driving information of the LED packages 4241. The LED packages 4241 may be the LED 10 (see FIG. 12) manufactured by using the LED manufacturing method according to the above-described exemplary embodiments.

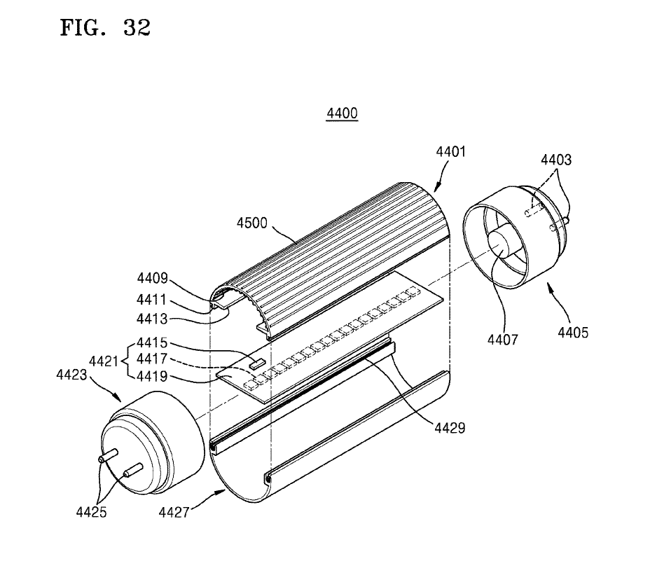

FIG. 32 is an exploded perspective view of a bar-type lighting apparatus 4400 including an LED manufacturing by using the LED manufacturing method according to an exemplary embodiment.

Referring to FIG. 27, the bar-type lighting apparatus 4400 may include a heat sink member 4401, a cover 4427, a light source module 4421, a first socket 4405, and a second socket 4423. A plurality of heat sink fins 4500 and 4409 having a concave/convex shape may be formed on inner or outer surfaces of the heat sink member 4401. The heat sink fins 4500 and 4409 may be designed to have various shapes and intervals. A support 4413 having a protruding shape may be formed inside the heat sink member 4401. The light source module 4421 may be fixed to the support 4413. Locking protrusions 4411 may be formed on both ends of the heat sink member 4401.

Locking grooves 4429 may be formed in the cover 4427. The locking protrusions 4411 of the heat sink member 4401 may be hooked to the locking grooves 4429. The positions of the locking grooves 4429 may be exchanged with the positions of the locking protrusions 4411.

The light source module 4421 may include an LED array. The light source module 4421 may include a PCB 4419, a light source 4417, and a controller 4415. The controller 4415 may store driving information of the light source 4417. Circuit wirings may be formed on the PCB 4419 so as to operate the light source 4417. In addition, the light source module 4421 may include components for operating the light source 4417. The light source 4417 may be at least one of the above-described LED 10 (see FIG. 12) manufactured by using the LED manufacturing method according to the exemplary embodiments.

The first and second sockets 4405 and 4423 may be provided as a pair of sockets and may be connected to both ends of a cylindrical cover unit including the heat sink member 4401 and the cover 4427. For example, the first socket 4405 may include an electrode terminal 4403 and a power supply 4407, and the second socket 4423 may include a dummy terminal 4425. In addition, an optical sensor module and/or a communication module may be embedded into the first socket 4405 or the second socket 4423. For example, the optical sensor module and/or the communication module may be embedded into the second socket 4423 in which the dummy terminal 4425 is arranged. As another example, the optical sensor module and/or the communication module may be embedded into the first socket 4405 in which the electrode terminal 4403 is arranged.

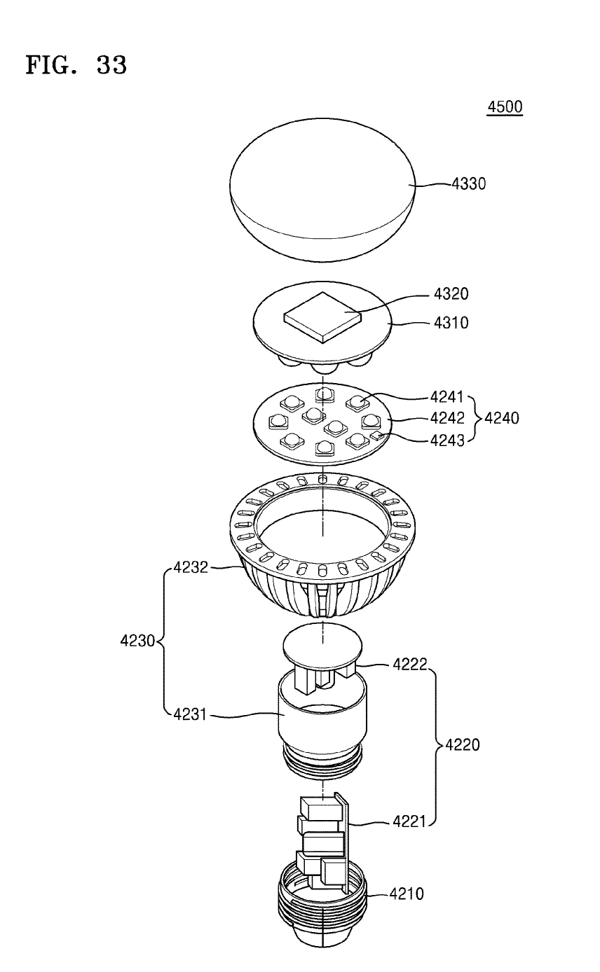

FIG. 33 is an exploded perspective view of a lighting apparatus 4500 including an LED manufacturing by using the LED manufacturing method according to an exemplary embodiment.

The lighting apparatus 4500 of FIG. 31 differs from the lighting apparatus 4200 of FIG. 26 in that a reflection plate 4310 and a communication module 4320 are provided on a light source module 4240. The reflection plate 4310 may uniformly disperse light from the light source in a lateral direction and a rearward direction so as to reduce glare.

The communication module 4320 may be mounted on the reflection plate 4310, and a home network communication may be performed through the communication module 4320. For example, the communication module 4320 may be a wireless communication module using ZigBee, WiFi, or LiFi, and control an indoor or outdoor lighting apparatus, such as on/off operations or brightness adjustment of the lighting apparatus through a smartphone or a wireless controller. In addition, electronic appliances and vehicle systems, such as TVs, refrigerators, air conditioners, doorlock systems, vehicles, may be controlled through a LiFi communication module using a wavelength of visible light in the indoor or outdoor lighting apparatus. The reflection plate 4310 and the communication module 4320 may be covered by the cover 4330.

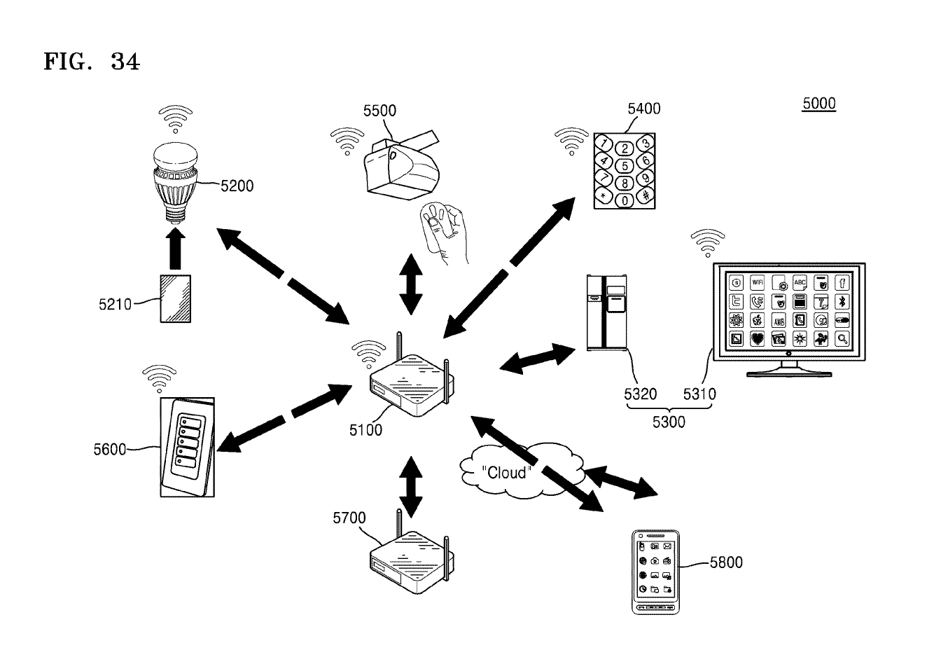

FIG. 34 is a diagram for describing an indoor lighting control network system 5000 including an LED manufacturing by using the LED manufacturing method according to an exemplary embodiment.

Referring to FIG. 34, the indoor lighting control network system 5000 may be a composite smart lighting-network system in which an illumination technology using an LED, an Internet of Things (IoT) technology, a wireless communication technology converge. The network system 5000 may be implemented using various lighting apparatuses and wired/wireless communication devices, and may be implemented by a sensor, a controller, a communication device, and software for network control and maintenance.

The network system 5000 may be applied to a closed space defined in buildings such as offices, an opening such as parks or streets, and the like. The network system 5000 may be implemented based on an IoT environment so as to collect, process, and provide a variety of information to users.

An LED lamp 5200 included in the network system 5000 may receive information about an ambient environment from a gateway 5100 and control illumination of the LED lamp 5200 itself. Furthermore, the LED lamp 5200 may check and control the operation states of other devices 5300 to 5800 included in the IoT environment based on a visible light communication function of the LED lamp 5200. The LED lamp 5200 may be the LED 10 (see FIG. 12) manufactured by using the LED manufacturing method according to the above-described exemplary embodiments.

The network system 5000 may include the gateway 5100 configured to process data transmitted and received in accordance with different communication protocols, the LED lamp 5200 communicably connected to the gateway 5100 and including an LED, and a plurality of devices 5300 to 5800 communicably connected to the gateway 5100 in accordance with various wireless communication schemes. In order to implement the network system 5000 based on the IoT environment, the devices 5300 to 5800, including the LED lamp 5200, may include at least one communication module. According to the exemplary embodiment, the LED lamp 5200 may be communicably connected to the gateway 5100 by the wireless communication protocol such as WiFi, ZigBee, or LiFi. To this end, the LED lamp 5200 may include at least one lamp communication module 5210.

The network system 5000 may be applied to a closed space such as homes or offices, an opening such as parks or streets, and the like. In a case where the network system 5000 is applied to the home, the plurality of devices 5300 to 5800, which are included in the network system 5000 and communicably connected to the gateway 5100 based on the IoT technology, may include electronic appliances 5300, a digital doorlock 5400, a garage doorlock 5500, a lighting switch 5600 installed on a wall, a router 5700 for relaying a wireless communication network, and mobile devices 5800 such as smartphones, tablets, or laptop computers.

In the network system 5000, the LED lamp 5200 may check the operation states of the various devices 5300 to 5800 or automatically control the illumination of the LED lamp 5200 itself according to the ambient environment and conditions by using the wireless communication network (e.g., ZigBee, WiFi, LiFi, etc.) installed at home. In addition, the LED lamp 5200 may control the devices 5300 to 5800 included in the network system 5000 through the LiFi communication using the visible light emitted by the LED lamp 5200.

The LED lamp 5200 may automatically control the illumination of the LED lamp 5200 based on the information about the ambient environment, which is transmitted from the gateway 5100 through the lamp communication module 5210, or the information about the ambient environment, which is collected from the sensor mounted on the LED lamp 5200. For example, the brightness of the LED lamp 5200 may be automatically adjusted according to a kind of a TV program aired on the TV 5310 or a screen brightness of the TV 5310. To this end, the LED lamp 5200 may receive operation information of the TV 5310 from the lamp communication module 5210 connected to the gateway 5100. The lamp communication module 5210 may be integrally modularized with the sensor and/or the controller included in the LED lamp 5200.

For example, when a program value of a TV program is a human drama, the LED lamp 5200 may lower a color temperature to 12,000K or less (e.g., 5,000K) and adjust a color sense according to a preset value, thus creating a cozy atmosphere. On the other hand, when a program value is a gag program, the LED lamp 5200 may increase a color temperature to 5,000K or more according to a set value so as to be adjusted to bluish white light.

In addition, after elapse of a predetermined time after the digital doorlock 5400 has been locked in such a state that there is no person at home, it is possible to prevent waste of electricity by turning off the turned-on LED lamp 5200. Alternatively, in a case where a security mode is set through the mobile device 5800 or the like, when the digital doorlock 5400 is locked in such a state that there is no person at home, the LED lamp 5200 may maintain the turned-on state.

The operation of the LED lamp 5200 may be controlled according to information about the ambient environment, which is collected through various sensors connected to the network system 5000. For example, in a case where the network system 5000 is implemented in a building, it is possible to turn on or off the illumination by combining a lighting apparatus, a position sensor, and a communication module within the building, or provide collected information in real time, thus enabling efficient facility management or efficient utilization of unused space. Because the lighting apparatus such as the LED lamp 5200 is usually arranged in almost all spaces of each floor in the building, a variety of information about the building may be collected through a sensor integrally provided with the LED lamp 5200, and the collected information may be used for facility management and utilization of unused spaces.

On the other hand, by combining the LED lamp 5200 with an image sensor, a storage device, the lamp communication module 5210, or the like, the LED lamp 5200 may be used as a device capable of maintaining building security or sensing and counteracting emergency situations. For example, when a smoke or temperature sensor is attached to the LED lamp 5200, it is possible to promptly detect an outbreak of fire, thus minimizing fire damage. In addition, it is possible to adjust the brightness of the lighting apparatus, save energy, and provide a pleasant illumination environment, taking into consideration outside weather or amount of sunshine.

As described above, the network system 5000 may be applied to a closed space such as homes, offices, or buildings, an opening such as parks or streets, and the like. In a case where the network system 5000 is intended to apply to an opening without physical limitations, it may be relatively difficult to implement the network system 5000 due to a distance limitation of wireless communication and a communication interference caused by various obstacles. By mounting the sensors and the communication modules on various lighting apparatuses and using the lighting apparatuses as information collection units and communication relay units, the network system 5000 may be more efficiently implemented in the open environments.

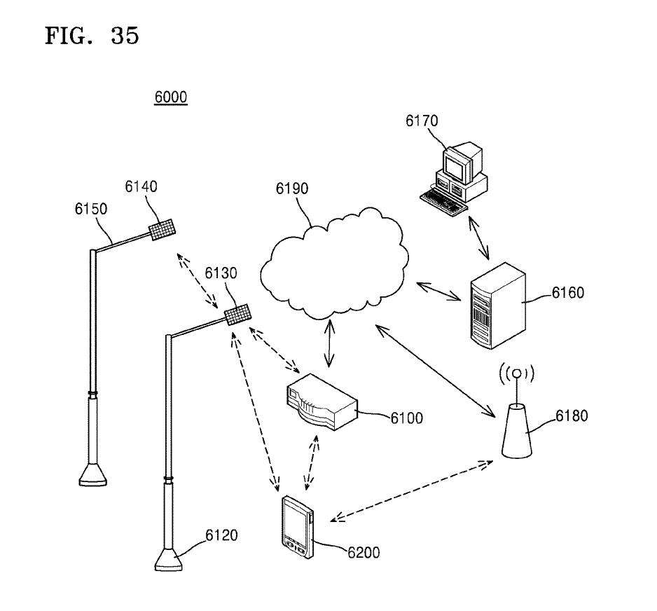

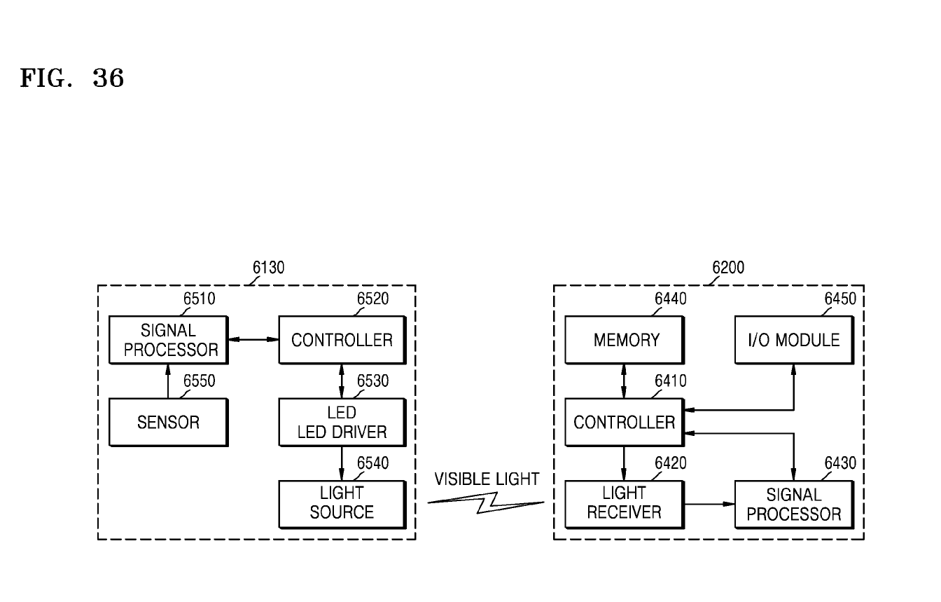

FIG. 35 is a diagram for describing a network system 6000 including an LED manufacturing by using the LED manufacturing method according to an exemplary embodiment.

FIG. 35 illustrates the network system 6000 applied to an opening. The network system 6000 may include a communication connecting device 6100, a plurality of lighting apparatuses 6120 and 6150 installed at predetermined intervals and communicably connected to the communication connecting device 6100, a server 6160, a computer 6170 configured to manage the server 6160, a communication base station 6180, a communication network 6190 configured to connect communicable devices, and a mobile device 6200.

The plurality of lighting apparatuses 6120 and 6150 installed in open external spaces such as streets or parts may include smart engines 6130 and 6140, respectively. Each of the smart engines 6130 and 6140 may include an LED configured to emit light, a driver configured to drive the LED, a sensor configured to collect information about an ambient environment, and a communication module. The LEDs included in the smart engine 6130 and 6140 may be the LED 10 (see FIG. 12) manufactured by using the LED manufacturing method according to the above-described exemplary embodiments.

The communication module may enable the smart engines 6130 and 6140 to communicate with other peripheral devices in accordance with the communication protocol such as WiFi, ZigBee, or LiFi.

For example, one smart engine 6130 may be communicably connected to the other smart engine 6140. In this case, a WiFi mesh may be applied to the communication between the smart engines 6130 and 6140. At least one smart engine 6130 may be connected to the communication connecting device 6100 connected to the communication network 6190 by a wired/wireless communication. In order to increase the efficiency of communication, the plurality of smart engines 6130 and 6140 may be grouped into one group and be connected to one communication connecting device 6100.

The communication connecting device 6100 may be an access point (AP) capable of performing wired/wireless communications and may relay a communication between the communication network 6190 and other devices. The communication connecting device 6100 may be connected to the communication network 6190 by at least one of the wired/wireless communication schemes. For example, the communication connecting device 6100 may be mechanically accommodated in one of the lighting apparatuses 6120 and 6150.

The communication connecting device 6100 may be connected to the mobile device 6200 through the communication protocol such as WiFi. A user of the mobile device 6200 may receive information about the ambient environment, which is collected by the plurality of smart engines 6130 and 6140, through the communication connecting device connected to the smart engine 6130 of the adjacent lighting apparatus 6120. The information about the ambient environment may include neighboring traffic information, weather information, and the like. The mobile device 6200 may be connected to the communication network 6190 through the communication base station 6180 by a wireless cellular communication scheme such as a 3G or 4G communication scheme.

On the other hand, the server 6160 connected to the communication network 6190 may receive information collected by the smart engines 6130 and 6140 respectively mounted on the lighting apparatuses 6120 and 6150 and may monitor the operation states of the lighting apparatuses 6120 and 6150. In order to manage the lighting apparatuses 6120 and 6150 based on the monitoring result of the operation states of the lighting apparatuses 6120 and 6150, the server 6160 may be connected to the computer 6170 that provides the management system. The computer 6170 may execute software capable of monitoring and managing the operation states of the lighting apparatuses 6120 and 6150, especially the smart engines 6130 and 6140.

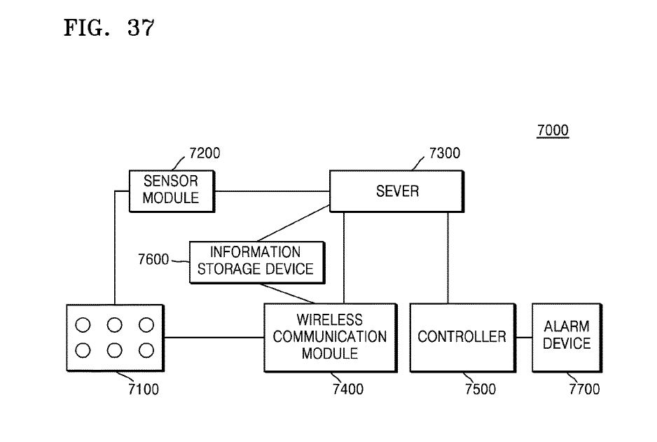

FIG. 36 is a block diagram for describing a communication operation between a smart engine 6130 of a lighting apparatus 6120 including an LED manufacturing by using the LED manufacturing method and a mobile device 6200, according to an exemplary embodiment.

FIG. 36 is a block diagram for describing a communication operation between the smart engine 6130 of the lighting apparatus 6120 of FIG. 35 and the mobile device 6200 via the visible light wireless communication. Various communication schemes may be applied for transmitting information collected by the smart engine 6130 to the mobile device 6200 of the user.

Through the communication connecting device (6100 of FIG. 35) connected to the smart engine 6130, the information collected by the smart engine 6130 may be transmitted to the mobile device 6200, or the smart engine 6130 and the mobile device 6200 may be directly communicable connected to each other. The smart engine 6130 and the mobile device 6200 may directly communicate with each other through the visible light wireless communication (LiFi).

The smart engine 6130 may include a signal processor 6510, a controller 6520, an LED driver 6530, a light source 6540, and a sensor 6550. The mobile device 6200, which is connected to the smart engine 6130 through the visible light wireless communication, may include a controller 6410, a light receiver 6420, a signal processor 6430, a memory 6440, and an input/output (I/O) module 6450.

The visible light wireless communication (LiFi) technology is a wireless communication technology that wirelessly transmits information by using light of a visible light wavelength the human may recognize with his/her eyes. The visible light wireless communication technology differs from the existing wired optical communication technology and infrared wireless communication in that the light of the visible light wavelength, that is, a specific frequency of visible light from the LED device package, is used, and differs from the wired optical communication technology in that communication environment is a wireless environment. Contrary to the RF wireless communication technology, the visible light wireless communication technology may freely be used without regulation or permission in terms of frequency use. In addition, the visible light wireless communication technology has excellent physical security and is different in that a user may confirm a communication link with his/her eyes. Furthermore, the visible light wireless communication technology is a convergence technology that is capable of simultaneously obtaining the unique purpose of the light source and the communication function.

The signal processor 6510 of the smart engine 6130 may process data to be transmitted and received through the visible light wireless communication. For example the signal processor 6510 may process information collected by the sensor 6550 into data and transmit the data to the controller 6520. The controller 6520 may control the operations of the signal processor 6510 and the LED driver 6530. In particular, the controller 6520 may control the operation of the LED driver 6530 based on the data transmitted by the signal processor 6510. The LED driver 6530 may transmit the data to the mobile device 6200 by turning on the light source 6540 according to a control signal transmitted by the controller 6520.

The mobile device 6200 may include the light receiver 6420 configured to recognize visible light including data, as well as the controller 6410, the memory 6440 configured to store data, the I/O module 6450 including a display, a touch screen, and an audio output unit, and the signal processor 6430. The light receiver 6420 may detect visible light and convert the detected visible light into an electrical signal. The signal processor 6430 may decode data included in the electrical signal. The controller 6410 may store the decoded data output from the signal processor 6430 in the memory 6440, or may output the decoded data through the I/O module 6450 so as to allow the user to recognize the decoded data.

FIG. 37 is a block diagram of a smart lighting system 7000 including an LED manufacturing by using the LED manufacturing method according to an exemplary embodiment.

Referring to FIG. 37, the smart lighting system 7000 may include an illumination module 7100, a sensor module 7200, a server 7300, a wireless communication module 7400, a controller 7500, and an information storage device 7600. The illumination module 7100 may include one or more lighting apparatuses installed in a building and there is no limitation to a type of the lighting apparatus. Examples of the lighting apparatus may include basic illuminations for a living room, a room, a balcony, a bathroom, stairs, and a front door, a mood illumination, a stand illumination, and a decorative illumination. The lighting apparatus may be the LED 10 (see FIG. 12) manufactured by using the LED manufacturing method according to the above-described exemplary embodiments.

The sensor module 7200 may detect illumination states related to the turn-on/off of each lighting apparatus and the intensity of the illumination, output a signal corresponding to the detected illumination state, and transmit the signal to the server 7300. The sensor module 7200 may be provided in the building where the lighting apparatus is installed. One or more sensors module 7200 may be at a position where the illumination states of all the lighting apparatuses controlled by the smart lighting system 7000 are detectable, or may be provided at each of the lighting apparatuses.

The information about the illumination state may be transmitted to the server 7300 in real time, or may be transmitted with a time difference based on predetermined time unit such as minute unit or hour unit. The server 7300 may be installed inside and/or outside the building. The server 7300 may receive a signal from the sensor module 7200, collect information about the illumination state, such as the turn-on/off of the lighting apparatus within the building, group the collected information, define an illumination pattern based on the grouped information, and provide information about the defined illumination pattern to the wireless communication module 7400. In addition, the server 7300 may serve as a medium that transmits a command received from the wireless communication module 7400 to the controller 7500.

Specifically, the server 7300 may receive the information about the illumination state of the building, which is detected and transmitted by the sensor module 7200, and collect and analyze the information about the illumination state. For example, the server 7300 may divide the collected information into various groups by period, such as time, day, day of week, weekdays and weekends, a preset specified day, a week, and a month. Then, the server 7300 may program a “defined illumination pattern” defined as an illumination pattern of an average day unit, week unit, weekday unit, weekend unit, and month unit based on the grouped information. The “defined illumination pattern” may be periodically provided to the wireless communication module 7400, or may be received from the server 7300 in response to a request for providing information when the user requests the information about the illumination pattern.

In addition, apart from the defining of the illumination pattern from the information about the illumination state received from the sensor module 7200, the server 7300 may provide the wireless communication module 7400 with a “normal illumination pattern” programmed in advance by reflecting a normal illumination state occurring at home. As in the case of the “defined illumination pattern”, the “normal illumination pattern” may be periodically provided from the server 7300, or may be provided when there is a request from a user. Only one server 7300 is illustrated in FIG. 37, but two or more servers may be provided when necessary. Optionally, the “normal illumination pattern” and/or the “defined illumination pattern” may be stored in the information storage device 7600. The information storage device 7600 may be a so-called cloud that is accessible via a network.

The wireless communication module 7400 may select one of the plurality of illumination patterns received from the server 7300 and/or the information storage device 7600 and transmit a command signal for executing or stopping an “automatic illumination mode” to the server 7300. The wireless communication module 7400 may be applied to various portable wireless communication devices such as smartphones, tablet PCs, PDAs, notebook computers, or netbook computers, which may be carried by the user of the smart lighting system.

Specifically, the wireless communication module 7400 may receive various defined illumination patterns from the server 7300 and/or the information storage device 7600, select necessary patterns from the received illumination patterns, and transmit a command signal to the server 7300 so as to execute the “automatic illumination mode” to operate the illumination module 7100 in the selected illumination pattern. The command signal may be transmitted at a set execution time. Alternatively, after the command signal is transmitted without defining a stop time, the execution of the “automatic illumination mode” may be stopped by transmitting a stop signal when necessary.

In addition, the wireless communication module 7400 may further have a function of allowing the user to partially modify the illumination pattern received from the server 7300 and/or the information storage device 7600 or manipulate a new illumination pattern when necessary. The modified or newly manipulated “user setting illumination pattern” may be stored in the wireless communication module 7400, may be automatically transmitted to the server 7300 and/or the information storage device 7600, or may be transmitted when necessary. In addition, the wireless communication module 7400 may automatically receive the “defined illumination pattern” and the “normal illumination pattern” from the server 7300 and/or the information storage device 7600, or may receive the “defined illumination pattern” and the “normal illumination pattern” by transmitting a provision request signal to the server 7300.

The wireless communication module 7400 may exchange a necessary command or information signal with the server 7300 and/or the information storage device 7600, and the server 7300 may serve as a medium between the wireless communication module 7400, the sensor module 7200, and the controller 7500. In this manner, the smart lighting system may be operated.

The connection between the wireless communication module 7400 and the server 7300 may be performed using an application program of the smartphone. That is, the user may instruct the server 7300 to execute the “automatic illumination mode” through an application program downloaded in the smartphone, or may provide information about the user setting illumination pattern” manipulated or modified by the user.

The information may be automatically provided to the server 7300 and/or the information storage device 7600 by the storing of the “user setting illumination pattern”, or may be provided by performing a transmission operation. This may be determined as a default of the application program, or may be selected by the user according to an option.

The controller 7500 may receive the command signal of executing or stopping the “automatic illumination mode” from the server 7300, and control one or more lighting apparatuses by executing the received command signal in the illumination module 7100. That is, the controller 7500 may control the turn-on/off or the like of the lighting apparatuses included in the illumination module 7100 according to the command signal from the server 7300.

In addition, the smart lighting system 7000 may further include an alarm device 7700 in the building. The alarm device 7700 may give an alarm when there is an intruder in the building.

Specifically, in a case where the “automatic illumination mode” is executed in the building in the absence of the user, when there is occurs an intruder in the building and there occurs an abnormal situation deviating from the set illumination pattern, the sensor module 7200 may detect the abnormal situation and transmit an alarm signal to the server 7300. The server 7300 may notify the wireless communication module 7400 of the abnormal situation and operate the alarm device 7700 in the building by transmitting a signal to the controller 7500.

In addition, when the alarm signal is transmitted to the server 7300, the server 7300 may further include a system that directly notifies a security company of an emergency situation via the wireless communication module 7400 or a TCP/IP network.

While exemplary embodiments have been particularly shown and described above, it will be understood that various changes in form and details may be made therein without departing from the spirit and scope of the inventive concept as defined by the following claims.

What is claimed is:

1. A method of manufacturing a light-emitting diode (LED), the method comprising:
preparing a substrate;
forming a plurality of semiconductor light-emitting units on the substrate, each of the plurality of semiconductor light-emitting units protruding from the substrate and comprising:
a first conductive semiconductor layer;
an active layer; and
a second conductive semiconductor layer, the active layer and the second conductive semiconductor layer sequentially covering the first conductive semiconductor layer;
dipping the semiconductor light-emitting units into an aqueous solution comprising:
metal salt; and
an alkaline ligand compound; and
forming an electrode layer on the plurality of semiconductor light-emitting units,
wherein the forming the electrode layer comprises maintaining a temperature of the aqueous solution between about 40° C. and about 200° C.

2. The method of claim 1, further comprising, after the forming the electrode layer, filling spaces between the plurality of semiconductor light-emitting units with a filler.

3. The method of claim 1, wherein:
the metal salt comprises zinc salt,
the alkaline ligand compound comprises ammonia, and
the electrode layer comprises a zinc oxide layer and is transparent.

4. The method of claim 1, wherein pH of the aqueous solution is between about 10 and about 12.

5. The method of claim 1, wherein the aqueous solution comprises about 0.1 mM to about 1000 mM of the metal salt.

6. The method of claim 1, wherein an aspect ratio of each of the plurality of semiconductor light-emitting units is at least 10:1.

7. The method of claim 1, wherein the forming the plurality of semiconductor light-emitting units comprises:
forming the first conductive semiconductor layer comprising a plurality of protruding units spaced apart from one another at uniform intervals on the substrate;
forming the active layer, the active layer covering side surfaces and upper surfaces of the plurality of protruding units; and
forming the second conductive semiconductor layer, the second conductive semiconductor layer covering side surfaces and upper surfaces of the active layer.

8. The method of claim 7, wherein the forming the first conductive semiconductor layer comprises:
forming a base layer on the substrate;
forming, on the base layer, a mask layer including an opening; and
selectively growing the first conductive semiconductor layer in the opening, using the base layer as a growth surface of the first conductive semiconductor layer.

9. The method of claim 1, wherein the forming the electrode layer comprises conformally forming the electrode layer such that the electrode layer covers side surfaces and upper surfaces of the semiconductor light-emitting units.

10. The method of claim 1, wherein a step coverage of the electrode layer is about 70% or above.

11. The method of claim 10, wherein the step coverage corresponds to a ratio of a thickness of a thickest portion of the electrode layer to a thickness of a thinnest portion of the electrode layer.

12. A method of manufacturing a light-emitting diode (LED), the method comprising:
preparing a substrate;
forming a plurality of semiconductor light-emitting units on the substrate, each of the plurality of semiconductor light-emitting units protruding from the substrate and comprising:
a core comprising a first conductive semiconductor layer; and
a shell comprising:
an active layer; and
a second conductive semiconductor layer, the active layer and the second conductive semiconductor layer sequentially covering the first conductive semiconductor layer;
dipping the plurality of semiconductor light-emitting units into an oxidized solution containing a metal source; and
forming an electrode layer on the plurality of semiconductor light-emitting units,
wherein the forming the electrode layer comprises maintaining a temperature of the oxidized solution between about 0° C. and about 100° C.

13. The method of claim 12, further comprising, after the forming the electrode layer, irradiating the electrode layer with ultraviolet rays.

14. The method of claim 12, wherein:
the metal source comprises a zinc foil,
the oxidized solution comprises an amide-based solution, and
the electrode layer comprises a zinc oxide layer.

15. The method of claim 12, wherein the electrode layer is transparent.

16. The method of claim 12, wherein the forming the electrode layer comprises conformally forming the electrode layer such that the electrode layer covers side surfaces and upper surfaces of the plurality of semiconductor light-emitting units.

17. A method of manufacturing a light-emitting diode (LED), the method comprising:
preparing a substrate;
forming a plurality of semiconductor light-emitting units on the substrate, each of the plurality of semiconductor light-emitting units protruding from the substrate and comprising:
a core comprising a first conductive semiconductor layer; and
a shell comprising:
an active layer; and
a second conductive semiconductor layer, the active layer and the second conductive semiconductor layer sequentially covering the first conductive semiconductor layer; and
dipping the plurality of semiconductor light-emitting units into an aqueous solution to coat each of the plurality of semiconductor light-emitting units with a transparent electrode layer, the aqueous solution comprising:
zinc salt; and
ammonia,
wherein the dipping the plurality of semiconductor light-emitting units comprises maintaining a temperature of the aqueous solution lower than about 200° C.

18. The method of claim 17, wherein the dipping the plurality of semiconductor light-emitting units comprises maintaining the temperature of the aqueous solution between about 40° C. and about 200° C.

19. The method of claim 17, wherein a ratio of a thickness of a thickest portion of the transparent electrode layer to a thickness of a thinnest portion of the transparent electrode layer is greater than or equal to 70%.

20. The method of claim 17 further comprising changing a ratio of Zn²⁺ ions of the zinc salt and the ammonia to control a growing speed of the transparent electrode layer.
